(19) United States
(12) Patent Application Publication
(10) Pub. No.: US 2023/0014830 A1
(43) Pub. Date: Jan. 19, 2023

(54) PIXEL AND DISPLAY DEVICE INCLUDING THE SAME

(71) Applicant: Samsung Display Co., LTD., Yongin-si (KR)

(72) Inventors: Hoon KIM, Yongin-si (KR); Je Won YOO, Yongin-si (KR); Yong Sik HWANG, Yongin-si (KR)

(21) Appl. No.: 17/743,366

(22) Filed: May 12, 2022

(30) Foreign Application Priority Data
Jul. 9, 2021 (KR) 10-2021-0090587

(51) Int. Cl. H01L 25/16; H01L 33/62; H01L 23/00

(52) U.S. Cl. CPC H01L 25/167; H01L 33/62; H01L 24/24; H01L 24/25; H01L 33/32

(57) ABSTRACT

A pixel may include first and second electrodes spaced apart from each other along a first direction, first light emitting elements arranged along a second direction in a first area between the first electrode and the second electrode, and including a first end portion adjacent to the first electrode and a second end portion adjacent to the second electrode, a first contact electrode on the first end portions of the first light emitting elements, and including a transparent electrode layer, a second contact electrode on the second end portions of the first light emitting elements, and including a reflective electrode layer, a first bank pattern overlapping a portion of the first electrode beneath the first electrode, and a second bank pattern overlapping a portion of the second electrode beneath the second electrode, wherein the first and second bank patterns are spaced apart from the first area by different distances.

### CROSS-REFERENCE TO RELATED APPLICATION

This application claims priority to, and the benefit of, Korean Patent Application No. 10-2021-0090587, filed on Jul. 9, 2021, the content of which in its entirety is herein incorporated by reference.

### BACKGROUND

### 1. Field

Embodiments of the disclosure relate to a pixel and a display device including the same.

### 2. Description of the Related Art

Recently, interest in information display is increasing. Accordingly, research and development of display devices have been continuously conducted.

### SUMMARY

An aspect of the disclosure provides a pixel capable of improving light efficiency and capable of more uniformly emitting light, and a display device including the same.

The aspects of the disclosure are not limited to the above-described aspect, and other aspects that are not described will be clearly understood by those skilled in the art from the following description.

A pixel according to one or more embodiments of the disclosure may include a first electrode and a second electrode spaced apart from each other along a first direction, first light emitting elements arranged along a second direction in a first area between the first electrode and the second electrode, and including a first end portion adjacent to the first electrode and a second end portion adjacent to the second electrode, a first contact electrode on the first end portions of the first light emitting elements, and including a transparent electrode layer, a second contact electrode on the second end portions of the first light emitting elements, and including a reflective electrode layer, a first bank pattern overlapping a portion of the first electrode beneath the first electrode, and a second bank pattern overlapping a portion of the second electrode beneath the second electrode, wherein the first bank pattern and the second bank pattern are spaced apart from the first area by different distances.

The first bank pattern may be spaced apart from the first area by a first distance in the first direction, wherein the second bank pattern is spaced apart from the first area in the first direction by a second distance that is shorter than the first distance.

The first bank pattern and the second bank pattern may have different widths in the first direction.

The first bank pattern may have a first width in the first direction, wherein the second bank pattern has a second width in the first direction that is narrower than the first width.

The first bank pattern and the second bank pattern may protrude at different heights in a third direction that crosses the first direction and the second direction.

The first bank pattern may have a first height in the third direction, wherein the second bank pattern has a second height in the third direction that is less than the first height.

The first bank pattern may include a first portion including a lower area having a height at or below a middle height of the first bank pattern, and a second portion including an upper area having a height at or above the middle height of the first bank pattern, wherein the first portion has a slope or an inclination that is greater than that of the second portion on a surface where the first bank pattern faces the first light emitting elements.

The first bank pattern may include a first portion including a lower area having a height at or below a middle height of the first bank pattern, and a second portion including an upper area having a height at or above than the middle height of the first bank pattern, wherein the second portion of the first bank pattern has a slope or an inclination that is greater than that of the first portion of the first bank pattern on a surface where the first bank pattern faces the first light emitting elements.

The pixel may further include a third electrode facing the first electrode in the first direction with the second electrode therebetween, second light emitting elements arranged along the second direction in a second area between the second electrode and the third electrode, and including a first end portion adjacent to the third electrode and a second end portion adjacent to the second electrode, a third contact electrode on the first end portions of the second light emitting elements, and including a transparent electrode layer, and a third bank pattern overlapping a portion of the third electrode beneath the third electrode, wherein the second bank pattern and the third bank pattern are spaced apart from the second area by different distances.

The first bank pattern may be at a greater distance from the first area in the first direction than the second bank pattern, wherein the third bank pattern is at a greater distance from the second area in the first direction than the second bank pattern.

The first bank pattern and the third bank pattern may protrude at a greater height than the second bank pattern in a third direction crossing the first direction and the second direction.

The first bank pattern and the third bank pattern may be symmetrical to each other with the second bank pattern interposed therebetween.

The pixel may further include an emission area where at least a portion of the first, second, and third electrodes, the first, second, and third contact electrodes, the second bank pattern, and the first and second light emitting elements are located, wherein the first bank pattern and the third bank pattern are integrated into an integrated bank pattern.

The integrated bank pattern may completely surround the emission area in a plan view.

The second contact electrode may be commonly on the second end portions of the first light emitting elements, and on the second end portions of the second light emitting elements.

The pixel may further include a fourth contact electrode on the second end portions of the second light emitting elements, and including a reflective electrode layer, wherein the second contact electrode is separated from the fourth contact electrode, and is electrically connected to the third contact electrode.

The first light emitting elements may include an active layer between the first end portion and the second end portion and closer to the first end portion than to the second end portion.

The pixel may further include a light conversion layer on the first light emitting elements in an emission area including the first area, the light conversion layer including at least one of wavelength conversion particles and light scattering particles.

A display device according to one or more embodiments of the disclosure may include a first electrode and a second electrode spaced apart from each other along a first direction, first light emitting elements arranged along a second direction in a first area between the first electrode and the second electrode, and including a first end portion adjacent to the first electrode and a second end portion adjacent to the second electrode, a first contact electrode on the first end portions of the first light emitting elements, and including a transparent electrode layer, a second contact electrode on the second end portions of the first light emitting elements, and including a reflective electrode layer, a first bank pattern overlapping a portion of the first electrode beneath the first electrode, and a second bank pattern overlapping a portion of the second electrode beneath the second electrode, and wherein the first bank pattern and the second bank pattern are spaced apart from the first area by different distances.

The first bank pattern may be spaced apart from the first area in the first direction by a greater distance than the second bank pattern, wherein the first bank pattern protrudes at a height that is higher than that of the second bank pattern in a third direction crossing the first direction and the second direction.

Details of other embodiments are included in the detailed description and drawings.

According to one or more embodiments of the disclosure, light output efficiency of light generated in the light emitting elements of the pixel may be increased. Accordingly, light efficiency of the pixel may be increased.

In addition, according to one or more embodiments of the disclosure, light may be more uniformly emitted from the emission area of the pixel. Accordingly, light emitting characteristic of the pixel may be improved.

Aspects according to the embodiments are not limited by the contents illustrated above, and other various aspects are included in the present specification.

### BRIEF DESCRIPTION OF THE DRAWINGS

The above and other aspects of the disclosure will become more apparent by describing in further detail embodiments thereof with reference to the accompanying drawings, in which:

FIG. 1 is a perspective view illustrating a light emitting element according to one or more embodiments of the disclosure;

FIG. 2 is a cross-sectional view illustrating a light emitting element according to one or more embodiments of the disclosure;

FIG. 3 is a plan view illustrating a display device according to one or more embodiments of the disclosure;

FIGS. 4 and 5 are circuit diagrams respectively illustrating a pixel according to one or more embodiments of the disclosure;

FIG. 6 is a plan view illustrating a pixel according to one or more embodiments of the disclosure;

FIGS. 7 to 9 are cross-sectional views respectively illustrating a pixel according to one or more embodiments of the disclosure;

FIGS. 10 to 12 are plan views respectively illustrating a pixel according to one or more embodiments of the disclosure;

FIG. 13 is a plan view illustrating a pixel according to one or more embodiments of the disclosure;

FIG. 14 is a cross-sectional view illustrating a pixel according to one or more embodiments of the disclosure;

FIG. 15 is a plan view illustrating a pixel according to one or more embodiments of the disclosure;

FIG. 16 is a cross-sectional view illustrating a pixel according to one or more embodiments of the disclosure;

FIG. 17 is a plan view illustrating a pixel according to one or more embodiments of the disclosure; and

FIG. 18 is a cross-sectional view illustrating a pixel according to one or more embodiments of the disclosure.

### DETAILED DESCRIPTION

Aspects of one or more embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware, to process data or digital signals. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Circuit hardware may include, for example, application specific integrated circuits (ASICs), general purpose or special purpose central processing units (CPUs) that is configured to execute instructions stored in a non-transitory storage medium, digital signal processors (DSPs), graphics processing units (GPUs), and programmable logic devices such as field programmable gate arrays (FPGAs).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

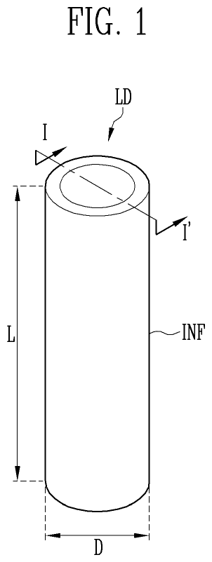

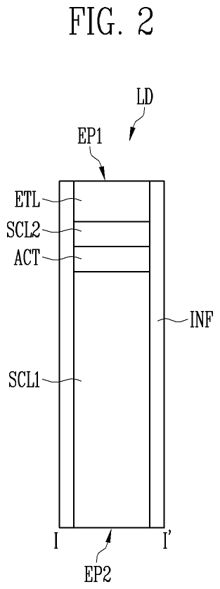

FIG. 1 is a perspective view illustrating a light emitting element LD according to one or more embodiments of the disclosure. FIG. 2 is a cross-sectional view illustrating a light emitting element LD according to one or more embodiments of the disclosure. For example, FIG. 1 illustrates an example of the light emitting element LD that may be used as a light source of a display device according to one or more embodiments of the disclosure, and FIG. 2 illustrates an example of a cross-sectional view of the light emitting element LD taken along the line I˜I′ of FIG. 1.

Referring to FIGS. 1 and 2, the light emitting element LD may include a first semiconductor layer SCL1, an active layer ACT, and a second semiconductor layer SCL2, which are sequentially located along one direction (for example, a length direction), and an insulating film INF surrounding an outer circumferential surface (for example, a side surface) of the first semiconductor layer SCL1, of the active layer ACT, and of the second semiconductor layer SCL2. In addition, the light emitting element LD may selectively further include an electrode layer ETL located on the second semiconductor layer SCL2. In this case, the insulating film INF may or may not at least partially surround an outer circumferential surface of the electrode layer ETL. In addition, according to one or more embodiments, the light emitting element LD may further include another electrode layer located on one surface (for example, a lower surface) of the first semiconductor layer SCL1.

In one or more embodiments, the light emitting element LD is provided in a bar (or rod) shape extending along one direction, and may have a first end portion EP1 and a second end portion EP2 at respective ends of a length direction (or a thickness direction). The first end portion EP1 may include a first base surface (or an upper surface) and/or a peripheral region thereof of the light emitting element LD, and the second end portion EP2 may include a second base surface (or a lower surface) and/or a peripheral region thereof of the light emitting element LD. For example, the electrode layer ETL and/or the second semiconductor layer SCL2 may be located on the first end portion EP1 of the light emitting element LD, and the first semiconductor layer SCL1 and/or at least one electrode layer connected to the first semiconductor layer SCL1 may be located on the second end portion EP2 of the light emitting element LD.

In describing embodiments of the disclosure, the term “bar shape” may include a rod-like shape or a bar-like shape having an aspect ratio greater than 1, such as a circular column or a polygonal column, and a shape of a cross section thereof is not particularly limited. For example, a length L of the light emitting element LD may be greater than a diameter D (or a width of the cross section) thereof.

The first semiconductor layer SCL1, the active layer ACT, the second semiconductor layer SCL2, and the electrode layer ETL may be sequentially located in a direction from the second end portion EP2 to the first end portion EP1 of the light emitting element LD. For example, the first semiconductor layer SCL1 may be located on the second end portion EP2 of the light emitting element LD, and the electrode layer ETL may be located on the first end portion EP1 of the light emitting element LD. Alternatively, at least one other electrode layer may be located on the second end portion EP2 of the light emitting element LD.

The first semiconductor layer SCL1 may be a semiconductor layer of a first conductivity type. For example, the first semiconductor layer SCL1 may be an N-type semiconductor layer including an N-type dopant. For example, the first semiconductor layer SCL1 may include any one semiconductor material among InAlGaN, GaN, AlGaN, InGaN, AlN, and InN, and may be an N-type semiconductor layer doped with a dopant such as Si, Ge, or Sn. However, the material configuring the first semiconductor layer SCL1 is not limited thereto, and various materials in addition to the above-described materials may configure the first semiconductor layer SCL1.

The active layer ACT may be located on the first semiconductor layer SCL1, and may be formed in a single-quantum well or multi-quantum well structure. A position of the active layer ACT may be variously changed according to a type of the light emitting element LD. In one or more embodiments, the active layer ACT may emit light having a wavelength of about 400 nm to about 900 nm, and may have a double hetero-structure.

In one or more embodiments, a clad layer doped with a conductive dopant may be selectively formed on and/or under the active layer ACT. For example, the clad layer may be formed of an AlGaN layer or an InAlGaN layer. According to one or more embodiments, a material such as AlGaN or AlInGaN may be used to form the active layer ACT, and various materials in addition to the above-described materials may configure the active layer ACT.

When a voltage equal to or greater than a threshold voltage is applied to both ends of the light emitting element LD, the light emitting element LD emits light while electron-hole pairs are combined in the active layer ACT. By controlling light emission of the light emitting element LD according to the above, the light emitting element LD may be used as a light source of various light emitting devices including a pixel of a display device.

The second semiconductor layer SCL2 may be located on the active layer ACT, and may be a semiconductor layer of a second conductive type that is different from that of the first semiconductor layer SCL1. For example, the second semiconductor layer SCL2 may include a P-type semiconductor layer including a P-type dopant. For example, the second semiconductor layer SCL2 may include at least one semiconductor material among InAlGaN, GaN, AlGaN, InGaN, AlN, and InN, and may be a P-type semiconductor layer doped with a dopant such as Mg. However, the material configuring the second semiconductor layer SCL2 is not limited thereto, and various materials in addition to the above-described materials may configure the second semiconductor layer SCL2.

In one or more embodiments, the first semiconductor layer SCL1 and the second semiconductor layer SCL2 may have different lengths (or thicknesses) in the length direction of the light emitting element LD. For example, the first semiconductor layer SCL1 may have a length (or a thickness) that is longer (or that is thicker) than that of the second semiconductor layer SCL2 along the length direction of the light emitting element LD. Accordingly, the active layer ACT may be positioned closer to the first end portion EP1 (for example, a P-type end portion) than the second end portion EP2 (for example, an N-type end portion).

The electrode layer ETL may be located on the second semiconductor layer SCL2. The electrode layer ETL may protect the second semiconductor layer SCL2, and may be an electrode for smoothly or stably connecting the second semiconductor layer SCL2 to an electrode, line, or the like (e.g., a predetermined electrode, line, or the like). For example, the electrode layer ETL may be an ohmic contact electrode or a Schottky contact electrode.

In one or more embodiments, the electrode layer ETL may be substantially translucent. Accordingly, light generated by the light emitting element LD may pass through the electrode layer ETL, and may be emitted from the first end portion EP1 of the light emitting element LD.

In one or more embodiments, the electrode layer ETL may include metal or metal oxide. For example, the electrode layer ETL may be formed using a metal such as chromium (Cr), titanium (Ti), aluminum (Al), gold (Au), nickel (Ni), or copper (Cu), oxide or alloy thereof, a transparent conductive material such as indium tin oxide (ITO), indium zinc oxide (IZO), indium tin zinc oxide (ITZO), zinc oxide (ZnO), or indium oxide (In₂O₃), and the like, alone or in combination.

The insulating film INF may expose the electrode layer ETL (or the second semiconductor layer SCL2) and the first semiconductor layer SCL1 (or another electrode layer provided at the second end portion EP2 of the light emitting element LD), respectively, at the first and second end portions EP1 and EP2 of the light emitting element LD.

In case that the insulating film INF is provided to cover a surface of the light emitting element LD, for example, to cover the outer circumferential surface of the first semiconductor layer SCL1, the active layer ACT, the second semiconductor layer SCL2, and/or the electrode layer ETL, a likelihood of a short defect through the light emitting element LD may be reduced or prevented. Accordingly, electrical stability of the light emitting element LD may be secured. In addition, in case that the insulating film INF is provided on the surface of the light emitting element LD, a surface defect of the light emitting element LD may be reduced or minimized, and thus, a lifespan and efficiency may be improved.

In one or more embodiments, the light emitting element LD may be manufactured through a surface treatment process. For example, by performing the surface treatment on the light emitting element LD using a hydrophobic material, when a plurality of light emitting elements LD are mixed in a fluid solution (hereinafter referred to as a “light emitting element mixed liquid” or a “light emitting element ink”), and are supplied to each emission area (for example, an emission area of a pixel), the light emitting elements LD may be substantially uniformly dispersed in the light emitting element mixed liquid without being non-uniformly aggregated.

The insulating film INF may include a transparent insulating material. Accordingly, light generated in the active layer ACT may pass through the insulating film INF and may be emitted to the outside of the light emitting element LD. For example, the insulating film INF may include at least one insulating material among silicon oxide (SiOₓ) (for example, SiO₂), silicon nitride (SiNₓ) (for example, Si₃N₄), aluminum oxide (AlₓO_{y}) (for example, Al₂O₃), titanium oxide (TiₓO_{y}) (for example, TiO₂), and hafnium oxide (HfOₓ), but is not limited thereto.

The insulating film INF may be configured of a single layer or of multiple layers. For example, the insulating film INF may be formed of a double film.

In one or more embodiments, the insulating film INF may be partially etched (or removed) in a region corresponding to at least one of the first end portion EP1 and the second end portion EP2 of the light emitting element LD. For example, the insulating film INF may be etched to have a rounded shape at the first end portion EP1, but the shape of the insulating film INF is not limited thereto.

In one or more embodiments, the light emitting element LD may have a small size in a range from nanometer (nm) to micrometer (μm). For example, each light emitting element LD may have the diameter D (or a width of a cross section) and/or the length L of the range from nanometer to micrometer. For example, the light emitting element LD may have the diameter D and/or the length L of a range of approximately about several tens of nanometers to about several tens of micrometers. However, a size of the light emitting element LD may be changed.

A structure, a shape, a size, and/or a type of the light emitting element LD may be changed according to one or more embodiments. For example, the light emitting element LD may be formed in another structure and/or shape such as a core-shell structure.

A light emitting device including the light emitting element LD may be used in various types of devices that require a light source. For example, the light emitting elements LD may be located in the pixel of the display device, and the light emitting elements LD may be used as a light source of the pixel. The light emitting element LD may be used in other types of devices that require a light source, such as a lighting device.

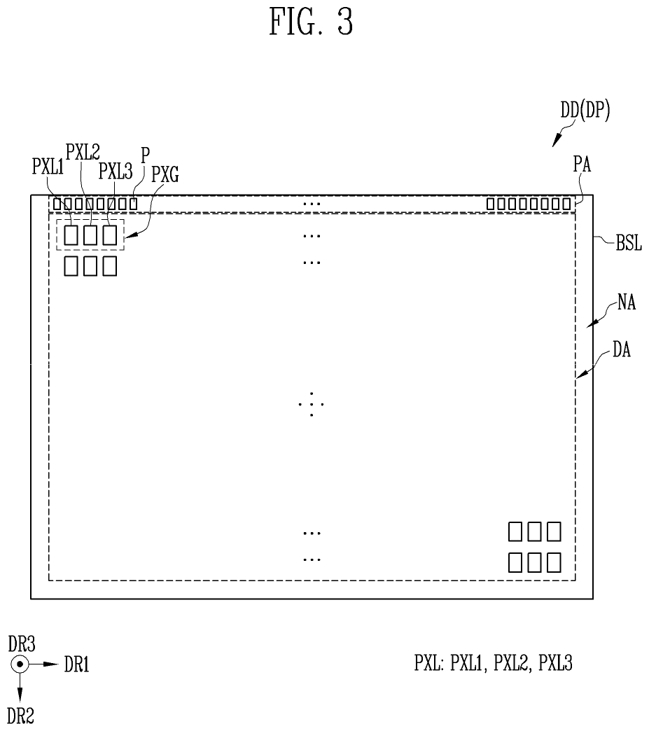

FIG. 3 is a plan view illustrating a display device DD according to one or more embodiments of the disclosure. In FIG. 3, a structure of the display device DD is briefly shown based on a display panel DP including a display area DA. The display device DD may further include a driving circuit (for example, a scan driver, a data driver, a timing controller, and the like) for driving pixels PXL.

Referring to FIG. 3, the display device DD may include a base layer BSL, and the pixels PXL located on the base layer BSL. The base layer BSL and the display device DD including the same may be provided in various shapes. For example, the base layer BSL and the display device DD may be provided in a plate shape having a substantially quadrangle shape when viewed in a plan view, and may include an angled or rounded corner portion. The shape of the base layer BSL and the display device DD may be changed. For example, the base layer BSL and the display device DD may have another polygonal shape such as a hexagon or an octagon when viewed in a plan view, or may have a shape including a curved perimeter such as a circle or an ellipse.

In FIG. 3, the display device DD is shown as having a plate shape of a quadrangle. In addition, a horizontal direction (for example, a row direction or a horizontal direction) of the display device DD is defined as a first direction DR1, a vertical direction (for example, a column direction or a vertical direction) of the display device DD is defined as a second direction DR2, a thickness direction (or a height direction) of the display device DD is defined as a third direction DR3.

The base layer BSL may be a base member for configuring the display device DD, and may configure, for example, a base surface of the display device DD. The base layer BSL may be a rigid substrate (for example, a glass substrate or a tempered glass substrate) of a hard material, or a flexible substrate or film of a flexible material and/or a thickness that may be deformed such as by bending, by folding, by curvedness, or the like. A material and a property of matter of the base layer BSL may be changed according to one or more embodiments.

The base layer BSL and the display device DD including the same may include the display area DA for displaying an image and a non-display area NA positioned around the display area DA.

The display area DA may be an area in which the pixels PXL are located, and may be an area in which an image is displayed by the pixels PXL. In one or more embodiments, the display area DA may be located, generally, in or near a center area (for example, a center area of the display panel DP) of the base layer BSL and the display device DD.

The display area DA may have various shapes. For example, the display area DA may have various shapes including a rectangle, a circle, or an ellipse. In one or more embodiments, the display area DA may have a shape corresponding to a shape of the base layer BSL, but is not limited thereto.

The non-display area NA may be a remaining area that excludes the display area DA. In one or more embodiments, the non-display area NA may be located at an edge area of the base layer BSL and the display device DD to surround the display area DA. A portion of the non-display area NA may be a pad area PA in which pads P are located.

The pixels PXL may be located in the display area DA. For example, the display area DA may include a plurality of pixel areas in which each pixel PXL is provided and/or located. The pixels PXL may be regularly arranged in the display area DA. The pixels PXL may be arranged in the display area DA according to a stripe or PENTILE™ arrangement structure, or may be arranged in the display area DA in another structure and/or method. PENTILE™ is a registered trademark of Samsung Display Co., Ltd., Republic of Korea.

In one or more embodiments, at least two types of pixels PXL for emitting light of different colors may be located in the display area DA. For example, in the display area DA, first color pixels PXL1, second color pixels PXL2, and third color pixels PXL3 may be arranged. At least one first color pixel PXL1, at least one second color pixel PXL2, and at least one third color pixel PXL3 located adjacent to each other may configure one pixel group PXG. By individually controlling a luminance of the first, second, and third color pixels PXL1, PXL2, and PXL3 included in each pixel group PXG, a color of light emitted from the pixel group PXG may be variously changed.

In one or more embodiments, the first color pixels PXL1, the second color pixels PXL2, and the third color pixels PXL3 successively arranged along the first direction DR1 may configure one pixel group PXG. However, the number, type, structure (e.g., mutual disposition structure), and/or the like of the pixels PXL configuring each pixel group PXG may be variously changed according to one or more embodiments.

In one or more embodiments, the first color pixel PXL1 may be a red pixel for emitting red light, and the second color pixel PXL2 may be a green pixel for emitting green light. In addition, the third color pixel PXL3 may be a blue pixel for emitting blue light. In addition, the color of the light emitted from the pixels PXL configuring each pixel group PXG may be variously changed.

In one or more embodiments, each pixel PXL may include at least one organic light emitting element and/or at least one inorganic light emitting element. For example, the pixel PXL may include the light emitting element LD according to one or more embodiments of FIGS. 1 and 2. For example, the pixel PXL may include the light emitting elements LD each including a single or multiple quantum wells and manufactured in a rod shape of a size belongs to an approximately nanometer to micrometer range. The number, type, structure, size, and/or the like of the light emitting elements LD configuring the light source of the pixel PXL may be variously changed according to one or more embodiments.

In one or more embodiments, the first color pixel PXL1, the second color pixel PXL2, and the third color pixel PXL3 may respectively include a first color light emitting element, a second color light emitting element, and a third color light emitting element as light sources. Accordingly, the first color pixel PXL1, the second color pixel PXL2, and the third color pixel PXL3 may emit light of a first color, light of a second color, and light of a third color, respectively.

In other embodiments, the first color pixel PXL1, the second color pixel PXL2, and the third color pixel PXL3 may include light emitting elements emitting light of the same color, and a light conversion layer including wavelength conversion particles (for example, particles that convert a color and/or a wavelength of light, such as a quantum dot QD) may be located in an emission area of the first color pixel PXL1, of the second color pixel PXL2, and/or of the third color pixel PXL3. Accordingly, the first color pixel PXL1, the second color pixel PXL2, and the third color pixel PXL3 may emit light of the first color, light of the second color, and light of the third color, respectively.

For example, the first color pixel PXL1, the second color pixel PXL2, and the third color pixel PXL3 may include blue light emitting elements, and a light conversion layer including a red quantum dot may be located in an emission area of the first color pixel PXL1, while a light conversion layer including a green quantum dot may be located in an emission area of the second color pixel PXL2. Accordingly, the first color pixel PXL1 may emit red light, and the second color pixel PXL2 may emit green light.

The pixels PXL may have a structure according to at least one or more of the embodiments to be described below. For example, the pixels PXL may have a structure to which one or more of the embodiments to be described later is applied, or may have a structure to which at least two embodiments are applied in combination.

In one or more embodiments, the pixel PXL may be configured as an active pixel, but is not limited thereto. For example, in other embodiments, the pixel PXL may be configured as a passive pixel.

Lines connected to the pixels PXL of the display area DA and/or a built-in circuit unit may be located in the non-display area NA. In addition, a portion of the non-display area NA may be set as the pad area PA, and the pads P may be located in the pad area PA. The pads P may include signal pads and/or power pads for supplying various driving signals and/or power suitable for driving the pixels PXL to the display device DD.

In one or more embodiments, the non-display area NA may have a narrow width. For example, the non-display area NA may have a width of about 100 micrometers or less. Accordingly, the display device DD may be implemented as a bezel-less display device.

The display device DD in which the non-display area NA is reduced may provide a larger screen compared to the entire size (for example, area). In addition, the display device DD in which the non-display area NA is reduced and/or removed may be usefully used to configure a tiling display device or the like.

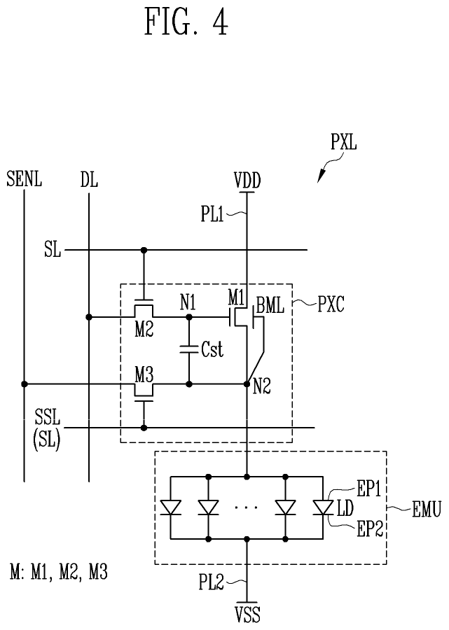

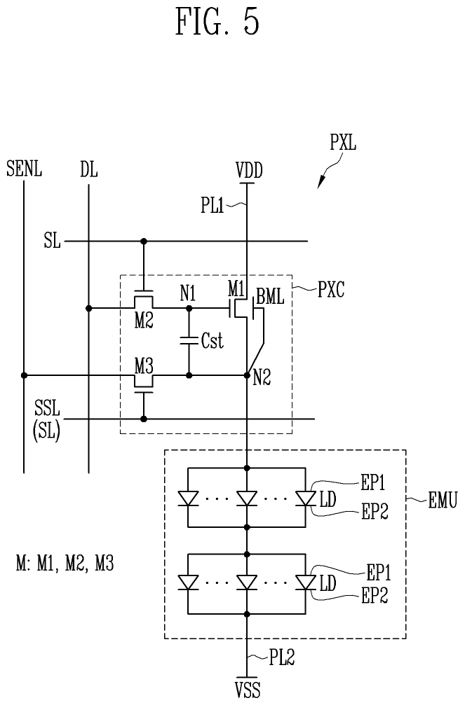

FIGS. 4 and 5 are respective circuit diagrams illustrating a pixel PXL according to one or more embodiments of the disclosure. For example, FIGS. 4 and 5 show the pixels PXL including light emitting units EMU of different respective structures.

According to one or more embodiments, each of the pixels PXL shown in FIGS. 4 and 5 may be any one of the pixels PXL located in the display area DA of FIG. 3. The pixels PXL may have substantially the same or similar structure to each other.

Referring to FIGS. 4 and 5, the pixel PXL may be connected to a scan line SL (also referred to as a “first scan line”), a data line DL, a first power line PL1, and a second power line PL2. In addition, the pixel PXL may be further connected to at least one other power line and/or signal line. For example, the pixel PXL may be further connected to a sensing line SENL (also referred to as an “initialization power line”) and/or a control line SSL (also referred to as a “second scan line”).

The pixel PXL may include the light emitting unit EMU for generating light of a luminance corresponding to each data signal. In addition, the pixel PXL may further include a pixel circuit PXC for driving the light emitting unit EMU.

The pixel circuit PXC may be connected to the scan line SL and the data line DL, and may be connected between the first power line PL1 and the light emitting unit EMU. For example, the pixel circuit PXC may be electrically connected to the scan line SL to which a first scan signal is supplied, the data line DL to which a data signal is supplied, the first power line PL1 to which first power VDD (e.g., a voltage or power of the first power source VDD) is supplied, and the light emitting unit EMU.

The pixel circuit PXC may be selectively further connected to the control line SSL to which a second scan signal is supplied, and the sensing line SENL connected to reference power (or initialization power) or a sensing circuit in response to a display period or a sensing period. In one or more embodiments, the second scan signal may be the same as, or different from, the first scan signal. When the second scan signal is the same as the first scan signal, the control line SSL may be integrated with the scan line SL.

The pixel circuit PXC may include at least one transistor M and a capacitor Cst. For example, the pixel circuit PXC may include a first transistor M1, a second transistor M2, a third transistor M3, and the capacitor Cst.

The first transistor M1 may be connected between the first power line PL1 and a second node N2. The second node N2 may be a node to which the pixel circuit PXC and the light emitting unit EMU are connected. For example, the second node N2 may be a node in which one electrode (for example, a source electrode) of the first transistor M1 and the light emitting unit EMU are electrically connected to each other. A gate electrode of the first transistor M1 may be connected to a first node N1. The first transistor M1 may control a driving current supplied to the light emitting unit EMU in response to a voltage of the first node N1. For example, the first transistor M1 may be a driving transistor of the pixel PXL.

In one or more embodiments, the first transistor M1 may further include a bottom metal layer (BML) (also referred to as a “back gate electrode” or a “second gate electrode”). In one or more embodiments, the bottom metal layer BML may be connected to the one electrode (for example, the source electrode) of the first transistor M1.

In one or more embodiments in which the first transistor M1 includes the bottom metal layer BML, there may be applied a back-biasing technique (or a sync technique) that moves a threshold voltage of the first transistor M1 in a negative direction or in a positive direction by applying a back-biasing voltage to the bottom metal layer BML of the first transistor M1. In addition, when the bottom metal layer BML is located under a semiconductor pattern configuring a channel of the first transistor M1, light incident on the semiconductor pattern may be blocked to stabilize an operation characteristic of the first transistor M1.

The second transistor M2 may be connected between the data line DL and the first node N1. In addition, a gate electrode of the second transistor M2 may be connected to the scan line SL. The second transistor M2 may be turned on when a first scan signal of a gate-on voltage (for example, a logic high voltage or a high level voltage) is supplied from the scan line SL, to thereby connect the data line DL and the first node N1.

In each frame period, the data signal of a corresponding frame may be supplied to the data line DL, and the data signal may be transmitted to the first node through the second transistor M2 during a period in which the first scan signal of the gate-on voltage is supplied. For example, the second transistor M2 may be a switching transistor for transmitting data signals to an inside of the pixel PXL.

A first electrode of the capacitor Cst may be connected to the first node N1, and a second electrode of the capacitor Cst may be connected to the second node N2. The capacitor Cst may charge a voltage corresponding to the data signal supplied to the first node N1 during each frame period.

The third transistor M3 may be connected between the second node N2 and the sensing line SENL. In addition, a gate electrode of the third transistor M3 may be connected to the control line SSL (or to the scan line SL or to another scan line). The third transistor M3 may be turned on when a second scan signal (or a first scan signal) of a gate-on voltage (for example, a logic high voltage or a high level voltage) is supplied from the control line SSL to thereby transmit the reference voltage (or the initialization voltage) supplied to the sensing line SENL to the second node N2, or to thereby transmit a voltage of the second node N2 to the sensing line SENL. In one or more embodiments, the voltage of the second node N2 may be transmitted to the sensing circuit through the sensing line SENL, and may be provided to the driving circuit (for example, the timing controller) to be used in compensation or the like of a characteristic deviation of the pixels PXL.

In FIGS. 4 and 5, all of the transistors M included in the pixel circuit PXC are N-type transistors, but embodiments are not limited thereto. For example, at least one of the first, second, and third transistors M1, M2, and M3 may be changed to a P-type transistor. The structure and driving method of the pixel PXL may be variously changed according to one or more embodiments.

The light emitting unit EMU may include at least one light emitting element LD. In one or more embodiments, the light emitting unit EMU may further include electrodes connected to the light emitting element LD (for example, at least one electrode connected to the first end portion EP1 of the light emitting element LD, and at least one electrode connected to the second end portion EP2 of the light emitting element LD).

In one or more embodiments, the light emitting unit EMU may include a plurality of light emitting elements LD connected in a forward direction between the first power source VDD and second power source VSS. The light emitting elements LD may configure an effective light source of the pixel PXL.

In one or more embodiments, the light emitting unit EMU may include the light emitting elements LD connected in parallel between the pixel circuit PXC and the second power line PL2 as shown in FIG. 4. The first end portions EP1 of the light emitting elements LD may be electrically connected to the pixel circuit PXC, and may be electrically connected to the first power line PL1 through the pixel circuit PXC. The second end portions EP2 of the light emitting elements LD may be electrically connected to the second power line PL2.

The number, type, and/or structure of the light emitting elements LD (for example, the light emitting elements LD connected in a forward direction between the first power source VDD and the second power source VSS) configuring the effective light source of the pixel PXL may be changed according to various embodiments. In addition, an arrangement and/or a connection structure of the light emitting elements LD may be changed according to various embodiments.

In one or more embodiments, the light emitting unit EMU may include the light emitting elements LD connected in series and in parallel between the pixel circuit PXC and the second power line PL2, as shown in FIG. 5. For example, the light emitting elements LD may be arranged and/or connected to at least two series stages between the pixel circuit PXC and the second power line PL2, and each series stage may include at least one light emitting element LD connected in a forward direction between the first power source VDD and the second power source VSS.

The first power source VDD and the second power source VSS may have different potentials. For example, the first power source VDD may be a high potential pixel power source, and the second power source VSS may be a low potential pixel power source. A potential difference between the first power source VDD and the second power source VSS may be equal to or greater than a threshold voltage of the light emitting elements LD.

The light emitting elements LD may emit light with a luminance corresponding to the driving current supplied through the pixel circuit PXC. During each frame period, the pixel circuit PXC may supply the driving current corresponding to the data signal to the light emitting unit EMU. The driving current supplied to the light emitting unit EMU may flow through the light emitting elements LD to cause the light emitting elements LD to emit light. Accordingly, the light emitting unit EMU may emit light with the luminance corresponding to the driving current.

FIGS. 4 and 5 show the light emitting elements LD (that is, effective light sources) connected only in a forward direction between the first power source VDD and the second power source VSS, but embodiments are not limited thereto. For example, the light emitting unit EMU may further include at least one light emitting element LD as an ineffective light source in addition to the light emitting elements LD configuring each effective light source. For example, the light emitting unit EMU may further include at least one ineffective light emitting element arranged in a reverse direction between the first power source VDD and the second power source VSS, or having at least one floating end portion.

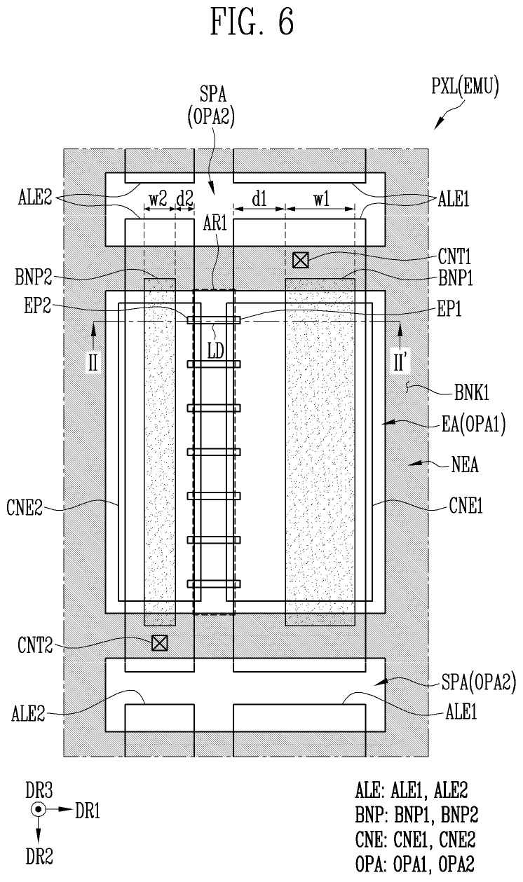

FIG. 6 is a plan view illustrating a pixel PXL according to one or more embodiments of the disclosure. In FIG. 6, a structure of the pixel PXL is shown based on the light emitting unit EMU. For example, FIG. 6 shows the light emitting unit EMU including the light emitting elements LD connected in parallel to each other as in the embodiments corresponding to FIG. 4.

Referring to FIGS. 3 to 6, the pixel PXL may include the light emitting elements LD, and a plurality of electrodes electrically connected to the light emitting elements LD. For example, the pixel PXL may include at least a pair of alignment electrodes ALE spaced apart from each other along the first direction DR1, the light emitting element LD located and/or aligned between the alignment electrodes ALE, and at least a pair of contact electrodes CNE respectively located on the first end portions EP1 and the second end portions EP2 of the light emitting elements LD.

In one or more embodiments, the pixel PXL may include a first alignment electrode ALE1 (also referred to as a “first electrode”) and a second alignment electrode ALE2 (also referred to as a “second electrode”) spaced apart from each other along the first direction DR1, the light emitting elements LD (also referred to as “first light emitting elements”) arranged along the second direction DR2 in a first area AR1 between the first alignment electrode ALE1 and the second alignment electrode ALE2, a first contact electrode CNE1 located on the first end portions EP1 of the light emitting elements LD, and a second contact electrode CNE2 located on the second end portions EP2 of the light emitting elements LD. The first contact electrode CNE1 may be electrically connected to the first end portions EP1 of the light emitting elements LD, and may be selectively connected to the first alignment electrode ALE1. The second contact electrode CNE2 may be electrically connected to the second end portions EP2 of the light emitting elements LD, and may be selectively connected to the second alignment electrode ALE2.

In addition, the pixel PXL may include bank patterns BNP (also referred to as “patterns” or “wall patterns”) located under each of the alignment electrodes ALE, and a first bank BNK1 defining an emission area EA of the pixel PXL. For example, the pixel PXL may include a first bank pattern BNP1 located under the first alignment electrode ALE1, a second bank pattern BNP2 located under the second alignment electrode ALE2, and the first bank BNK1 surrounding the emission area EA of the pixel PXL.

At least a portion of each of the first and second alignment electrodes ALE1 and ALE2, the light emitting elements LD, the first and second contact electrodes CNE1 and CNE2, and the first and second bank patterns BNP1 and BNP2 may be located in the emission area EA of the pixel PXL.

A non-emission area NEA may be located around the emission area EA of the pixel PXL, and the first bank BNK1 may be located in the non-emission area NEA. For example, the first bank BNK1 may have a first opening OPA1 corresponding to the emission area EA of each pixel PXL, and may surround the emission area EA. In addition, the first bank BNK1 may further include second openings OPA2 corresponding to one area of the non-emission area NEA and/or separation areas SPA positioned around the non-emission area NEA. End portions of at least one of the first alignment electrode ALE1 and the second alignment electrode ALE2 may be located in the second openings OPA2.

The first bank pattern BNP1 may overlap a portion of the first alignment electrode ALE1, and may be located under the first alignment electrode ALE1. The first bank pattern BNP1 may be located around the first end portions EP1 of the light emitting elements LD. For example, when viewed on a plane (for example, an XY plane) defined by the first direction DR1 and the second direction DR2, the first bank pattern BNP1 may be positioned at a point spaced apart from the first area AR1 by a first distance d1, and may be spaced apart from the light emitting elements LD. The first bank pattern BNP1 may face the first end portions EP1 of the light emitting elements LD.

The first bank pattern BNP1 may or may not overlap the first bank BNK1. For example, a portion of the first bank pattern BNP1 may be located in the emission area EA, and another portion of the first bank pattern BNP1 (for example, at least one end portion of the first bank pattern BNP1) may be located in the non-emission area NEA to overlap the first bank BNK1. Alternatively, the first bank pattern BNP1 may be located only inside the emission area EA so as not to overlap the first bank BNK1.

The second bank pattern BNP2 may overlap a portion of the second alignment electrode ALE2, and may be located under the second alignment electrode ALE2. The second bank pattern BNP2 and the second alignment electrode ALE2 may be located around the second end portions EP2 of the light emitting elements LD. For example, when viewed on the plane defined by the first direction DR1 and the second direction DR2, the second bank pattern BNP2 may be positioned at a point spaced apart from the first area AR1 by a second distance d2, and may be spaced apart from the light emitting elements LD. The second bank pattern BNP2 may face the second end portions EP2 of the light emitting elements LD.

The second bank pattern BNP2, or a portion thereof, may or may not overlap the first bank BNK1. For example, a portion of the second bank pattern BNP2 may be located in the emission area EA, and another portion of the second bank pattern BNP2 (for example, at least one end portion of the second bank pattern BNP2) may be located in the non-emission area NEA to overlap the first bank BNK1. Alternatively, the second bank pattern BNP2 may be located only inside the emission area EA so as not to overlap the first bank BNK1.

The first alignment electrode ALE1 may be located around the first end portions EP1 of the light emitting elements LD. The first alignment electrode ALE1 may or may not overlap the first end portion EP1 of each of the light emitting elements LD.

The second alignment electrode ALE2 may be located around the second end portions EP2 of the light emitting elements LD. The second alignment electrode ALE2 may or may not overlap the second end portion EP2 of each of the light emitting elements LD.

The first and second alignment electrodes ALE1 and ALE2 may have various shapes, and may be spaced apart from each other. In one or more embodiments, the first and second alignment electrodes ALE1 and ALE2 may be spaced apart from each other along the first direction DR1 in the emission area EA, and each of the first and second alignment electrodes ALE1 and ALE2 may have a shape extending along the second direction DR2 (for example, a bar shape). In addition, the first and second alignment electrodes ALE1 and ALE2 may have a shape and/or size similar to, or the same as, each other, or may have different shapes and sizes. The shape, size, number, and/or mutual disposition structure of the first and second alignment electrodes ALE1 and ALE2 may be changed according to one or more embodiments.

The first and second alignment electrodes ALE1 and ALE2 may be located in the emission area EA. In one or more embodiments, the first and second alignment electrodes ALE1 and ALE2 may extend from the emission area EA to the non-emission area NEA. In one or more embodiments, the first and second alignment electrodes ALE1 and ALE2 may extend to the separation areas SPA corresponding to the second openings OPA2 of the first bank BNK1, and both end portions of the second alignment electrodes ALE1 and ALE2 may be at the separation areas SPA.

The first alignment electrode ALE1 may have a pattern separated for each pixel PXL. The second alignment electrode ALE2 may have a pattern separated for each pixel PXL. In some embodiments, the second alignment electrodes ALE2 of at least two pixels PXL adjacent along the first direction DR1 and/or the second direction DR2 may be integrally connected.

Meanwhile, before a pixel process for forming the pixels PXL, for example, before an alignment of the light emitting elements LD is completed, the first alignment electrodes ALE1 of adjacent pixels PXL may be connected to each other, and the second alignment electrodes ALE2 of adjacent pixels PXL may be connected to each other. For example, before the alignment of the light emitting elements LD is completed, the first alignment electrodes ALE1 of the pixels PXL may be integrally or non-integrally formed with each other, may be electrically connected to each other, and may form a first alignment line. The second electrodes ALE2 of the pixels PXL may be integrally or non-integrally formed with each other, may be electrically connected to each other, and may configure a second alignment line.

The first alignment line and the second alignment line may receive a first alignment signal and a second alignment signal, respectively, in an alignment operation for aligning the light emitting elements LD. The first and second alignment signals may have different waveforms, potentials, and/or phases. Accordingly, an electric field may be formed between the first and second alignment lines, and thus the light emitting elements LD may be aligned between the first and second alignment lines.

For example, in the light emitting element alignment operation, the light emitting elements LD may be arranged along the second direction DR2 in an area between the first and second alignment lines (for example, at an area including the first area AR1) by the first and second alignment signals respectively applied to the first and second alignment lines. In addition, each light emitting element LD may be aligned in the first area AR1 so that the first end portion EP1 thereof is adjacent to the first alignment electrode ALE1, and a second end portion EP2 thereof is adjacent to the second alignment electrode ALE2. For example, each of the light emitting elements LD may be horizontally aligned in the first direction DR1.

After the alignment of the light emitting elements LD is completed, the first alignment line may be cut off in each separation area SPA. Accordingly, the first alignment electrodes ALE1 of the pixels PXL may be formed to be separated from each other, and the pixels PXL may be individually driven.

In one or more embodiments, the second alignment electrodes ALE2 of the pixels PXL may be separated while the first alignment electrodes ALE1 of the pixels PXL are separated. For example, after the alignment of the light emitting elements LD is completed, the first and second alignment lines may be cut off in each separation area SPA. Accordingly, the first and second alignment electrodes ALE1 and ALE2 of the pixels PXL may be formed in respective individual patterns.

The first alignment electrode ALE1 may overlap the first bank pattern BNP1, and may protrude in the third direction DR3 (for example, in a height direction) crossing (for example, being orthogonal to) the first direction DR1 and the second direction DR2 at an area overlapping the first bank pattern BNP1. The second alignment electrode ALE2 may overlap the second bank pattern BNP2, and may protrude in the third direction DR3 in an area overlapping the second bank pattern BNP2.

A first protrusion pattern may be formed on one side (for example, a right side) of the first area AR1 by the first alignment electrode ALE1 and the first bank pattern BNP1. A second protrusion pattern may be formed on another side (for example, a left side) of the first area AR1 by the second alignment electrode ALE2 and the second bank pattern BNP2. A position at which the light emitting elements LD are aligned and/or arranged may be more suitably controlled by the first and second protrusion patterns.

In addition, at least one of the first and second protrusion patterns may form a reflective wall structure for reflecting the light emitted from the light emitting elements LD, and for emitting the light, generally, in an upper direction. For example, assuming that the light emitting elements LD emit the light through respective first end portions EP1, the light emitted from the first end portions EP1 of the light emitting elements LD in a lateral direction toward the first protrusion pattern may be reflected from the first protrusion pattern, and may be emitted in the upper direction of the pixel PXL by the first protrusion pattern formed by the first alignment electrode ALE1 and the first bank pattern BNP1. Accordingly, light efficiency of the pixel PXL may be increased.

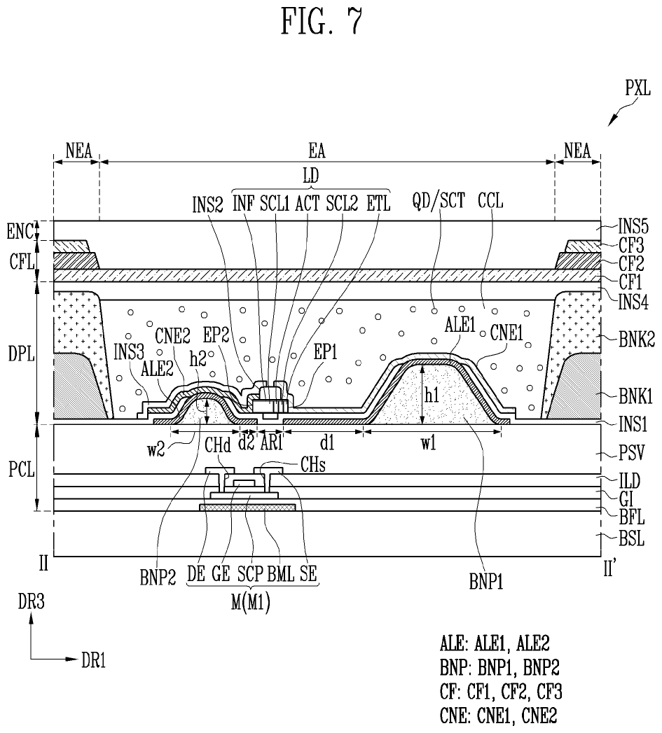

In one or more embodiments, the first alignment electrode ALE1 may be electrically connected to the first contact electrode CNE1. For example, the first alignment electrode ALE1 may be in direct contact with the first contact electrode CNE1 inside and/or outside the emission area EA to be electrically connected to the first contact electrode CNE1, or may be electrically connected to the first contact electrode CNE1 through at least one contact hole or the like. The first alignment electrode ALE1 may be connected to the pixel circuit PXC of the pixel PXL through a first contact portion CNT1. For example, the first alignment electrode ALE1 may be electrically connected to the first transistor M1 or the like located in a circuit layer (for example, a circuit layer PCL of FIG. 7) through the first contact portion CNT1. The first contact electrode CNE1 may be electrically connected to the pixel circuit PXC through the first alignment electrode ALE1.

The first contact portion CNT1 may include at least one contact hole and/or via hole. In one or more embodiments, the first contact portion CNT1 may be located outside the emission area EA. For example, the first contact portion CNT1 may be located in the non-emission area NEA so as to overlap the first bank BNK1, or may be located in the separation area SPA so as not to overlap the first bank BNK1. A position of the first contact portion CNT1 may be changed.

In one or more embodiments, the second alignment electrode ALE2 may be electrically connected to the second contact electrode CNE2. For example, the second alignment electrode ALE2 may be in direct contact with the second contact electrode CNE2 inside and/or outside the emission area EA to be electrically connected to the second contact electrode CNE2, or may be electrically connected to the second contact electrode CNE2 through at least one contact hole or the like. The second alignment electrode ALE2 may be electrically connected to the second power line PL2 located in the circuit layer (for example, the circuit layer PCL of FIG. 7) through a second contact portion CNT2.

The second contact portion CNT2 may include at least one contact hole and/or via hole. In one or more embodiments, the second contact portion CNT2 may be located outside the emission area EA. For example, the second contact portion CNT2 may be located in the non-emission area NEA so as to overlap the first bank BNK1, or may be located in the separation area SPA so as not to overlap the first bank BNK1. A position of the second contact portion CNT2 may be changed.

The light emitting elements LD may be located in the first area AR1 between the first and second alignment electrodes ALE1 and ALE2. Here, a case where the light emitting elements LD are located in the first area AR1 may mean that at least a portion of each of the light emitting elements LD is located in the first area AR1. Each light emitting element LD may include the first end portion EP1 adjacent to the first alignment electrode ALE1, and the second end portion EP2 adjacent to the second alignment electrode ALE2.

For example, the light emitting elements LD may be arranged along the second direction DR2 in the first area AR1. In addition, in some embodiments, each of the light emitting elements LD may be aligned in a direction (for example, in the first direction DR1, or close thereto, or in an oblique direction) crossing the second direction DR2 so that the first end portion EP1 is adjacent to the first alignment electrode ALE1 and the second end portion EP2 is adjacent to the second alignment electrode ALE2.

The first end portions EP1 of the light emitting elements LD may overlap the first contact electrode CNE1, and may be electrically connected to the first contact electrode CNE1. The second end portions EP2 of the light emitting elements LD may overlap the second contact electrode CNE2, and may be electrically connected to the second contact electrode CNE2.

In one or more embodiments, each light emitting element LD may be an inorganic light emitting element using a material having an inorganic crystal structure (for example, having a size of a nanometer to micrometer range). For example, each light emitting element LD may be an inorganic light emitting element (for example, the light emitting element LD according to the embodiments corresponding to FIGS. 1 and 2) manufactured by growing a nitride-based semiconductor, and by etching the nitride-based semiconductor into a rod shape of a nanometer to micrometer size. However, the type, size, shape, structure, number, and/or the like of the light emitting element(s) LD configuring each light emitting unit EMU may be changed.

The light emitting elements LD may be prepared in a dispersed form in a fluid solution, and may be supplied to the emission area EA of each pixel PXL through an inkjet method or a slit coating method. The light emitting elements LD may be aligned and/or arranged in the first area AR1 by respectively applying the first and second alignment signals to the first and second alignment lines concurrently or substantially simultaneously with or after the supply of the light emitting elements LD. After the light emitting elements LD are aligned, a solvent may be removed through a drying process or the like.

The first contact electrode CNE1 may be located on the first alignment electrode ALE1 and on the first end portions EP1 of the light emitting elements LD. In one or more embodiments, the first contact electrode CNE1 may be electrically connected to the first end portions EP1 of the light emitting elements LD. For example, the first contact electrode CNE1 may be directly located on the first end portions EP1 of the light emitting elements LD to be in contact with the first end portions EP1 of the light emitting elements LD.

In one or more embodiments, the first contact electrode CNE1 may be electrically connected to the first alignment electrode ALE1, and may be electrically connected to the pixel circuit PXC and/or the first power line PL1 through the first alignment electrode ALE1. In other embodiments, the first contact electrode CNE1 may be electrically connected to the pixel circuit PXC and/or the first power line PL1 through means other than the first alignment electrode ALE1.

The second contact electrode CNE2 may be located on the second alignment electrode ALE2 and on the second end portions EP2 of the light emitting elements LD. In one or more embodiments, the second contact electrode CNE2 may be electrically connected to the second end portions EP2 of the light emitting elements LD. For example, the second contact electrode CNE2 may be directly located on the second end portions EP2 of the light emitting elements LD to be in contact with the second end portions EP2 of the light emitting elements LD.

In one or more embodiments, the second contact electrode CNE2 may be electrically connected to the second alignment electrode ALE2, and may be electrically connected to the second power line PL2 through the second alignment electrode ALE2. In other embodiments, the second contact electrode CNE2 may be electrically connected to the second power line PL2 through means other than the second alignment electrode ALE2.

In one or more embodiments, the first contact electrode CNE1 and the second contact electrode CNE2 may be electrically connected to the first alignment electrode ALE1 and the second alignment electrode ALE2 in the emission area EA, respectively, but embodiments are not limited thereto. The disposition structure, connection or lack thereof, a connection position, the number, and/or the like of the alignment electrodes ALE and the contact electrodes CNE may be changed according to one or more embodiments.

In one or more embodiments, the first contact electrode CNE1 may be a transparent electrode including at least one transparent electrode layer, and the second contact electrode CNE2 may be a reflective electrode including at least one reflective electrode layer. For example, the first contact electrode CNE1 may be formed of a transparent electrode of a single layer or of multiple layers including at least one transparent conductive material, and the second contact electrode CNE2 may be formed of a reflective electrode of a single layer or of multiple layers including at least one reflective conductive material (for example, metal). Accordingly, the light emitting elements LD may mainly emit light through the first end portions EP1. For example, the light emitting elements LD may emit light only through the first end portions EP1 of the first and second end portions EP1 and EP2.

At least some of the light emitted through the first end portions EP1 of the light emitting elements LD may be reflected by the first protrusion pattern formed by the first bank pattern BNP1 and the first alignment electrode ALE1 in an area where the first bank pattern BNP1 is formed, and may be emitted in the upper direction of the pixel PXL including the third direction DR3. Accordingly, light output efficiency of the light generated in the pixel PXL may be increased.

In one or more embodiments, the first bank pattern BNP1 and the second bank pattern BNP2 may have an asymmetric structure. For example, a separation distance between the first bank pattern BNP1 and the first area AR1, and a separation distance between the second bank pattern BNP2 and the first area AR1, and/or a size (for example, a width, an area, a height and/or a volume) of the first bank pattern BNP1 and a size of the second bank pattern BNP2, may be different from each other. In one or more embodiments, the first bank pattern BNP1 and the second bank pattern BNP2 may have different surface profiles.

In one or more embodiments, the first bank pattern BNP1 and the second bank pattern BNP2 may be located at positions spaced apart from the first area AR1 by different respective distances. For example, in the first direction DR1, the first bank pattern BNP1 may be spaced apart from the first area AR1 by a first distance d1, and the second bank pattern BNP2 may be spaced apart from the first area AR1 by a second distance d2 that is shorter than the first distance d1.

In one or more embodiments, the first distance d1 may be determined according to a path and/or a distribution of the light emitted from the light emitting elements LD. For example, the first distance d1 may be within a range capable of enabling the first protrusion pattern to effectively reflect a light of a lateral direction, which is emitted at a relatively low angle without being directed in the upper direction of the pixel PXL, among the light emitted from the first end portions EP1 of the light emitting elements LD.

In one or more embodiments, the second distance d2 may be set to a value that is less than the first distance d1 in consideration of a limited pixel area. For example, the second bank pattern BNP2 may be located close to the first area AR1 so that the second distance d2 is reduced or minimized in consideration of the width of the emission area EA along the first direction DR1 and/or in consideration of the entire area of the emission area EA. Accordingly, the limited pixel area may be efficiently utilized, and a separation distance between the first bank pattern BNP1 and the first area AR1 may be sufficiently secured.

For example, the first bank pattern BNP1 may be formed in a sufficient size at a position where a greater proportion of the light of a low angle, which is emitted from the first end portions EP1 of the light emitting elements LD, may be effectively reflected. The second bank pattern BNP2 may be located closer to the first area AR1 than the first bank pattern BNP1, and may be formed to be of a size that is less than that of the first bank pattern BNP1.

In one or more embodiments, the first bank pattern BNP1 may be formed to be higher than, or thicker than, the second bank pattern BNP2, and may have a width that is greater than that of the second bank pattern BNP2 along the first direction DR1. For example, the first bank pattern BNP1 and the second bank pattern BNP2 may have different widths in the first direction DR1. For example, in the first direction DR1, the first bank pattern BNP1 may have a first width w1, and the second bank pattern BNP2 may have a second width w2 that is narrower than the first width w1. Accordingly, a space utilization rate of the pixel area (for example, the emission area EA) may be increased while increasing the light output efficiency of the light generated in the pixel PXL.

The first bank BNK1 may be located in the non-emission area NEA around the emission area EA to surround the emission area EA of each of the pixels PXL. For example, the first bank BNK1 may be located in an outer area of each of the pixels PXL and/or in an area between adjacent pixels PXL to surround each emission area EA.

The first bank BNK1 may include the first openings OPA1 corresponding to the emission areas EA of the pixels PXL. In addition, the first bank BNK1 may further include the second openings OPA2 corresponding to the separation areas SPA. For example, the first bank BNK1 may include openings OPA corresponding to the emission areas EA and the separation areas SPA across an entirety of the display area DA, and may have a mesh shape. As the first bank BNK1 includes the second openings OPA2 corresponding to the separation areas SPA, after the alignment of the light emitting elements LD is completed, the first and second alignment lines (or the first alignment line) may be suitably separated into the first and second alignment electrodes ALE1 and ALE2 (or into the first alignment electrodes ALE1).

The first bank BNK1 may include at least one light blocking and/or reflective material. For example, the first bank BNK1 may include at least one black matrix material, color filter material of a corresponding color, and/or the like. Accordingly, light leakage between adjacent pixels PXL may be reduced or prevented.

In addition, the first bank BNK1 may define each emission area EA to which the light emitting elements LD are to be supplied during the operation of supplying the light emitting elements LD to each pixel PXL. For example, as the emission areas EA of the pixels PXL are separated and partitioned by the first bank BNK1, a desired type and/or amount of a light-emitting-diode-mixed liquid (for example, a light emitting element ink including light emitting elements LD of at least one type and/or color) may be supplied.

FIGS. 7 to 9 are cross-sectional views illustrating a pixel PXL according to one or more embodiments of the disclosure, respectively. For example, FIGS. 7 to 9 illustrate cross-sectional views of the pixel PXL taken along the line II˜II′ of FIG. 6, and illustrate different embodiments in relation to the first bank pattern BNP1. In the embodiments of FIGS. 7 to 9, the same reference numerals are given to configurations substantially similar to or identical to each other, and a detailed description of repetitive parts is omitted.

In FIGS. 7 to 9, as an example of circuit elements that may be located in the circuit layer PCL of the pixel PXL and the display device DD including the same, a cross section of any one transistor M (for example, the first transistor M1 including the bottom metal layer BML) provided in each pixel circuit PXC is shown as an example. Various signal lines and/or power lines may be further located in the circuit layer PCL in addition to circuit elements included in each pixel circuit PXC.

First, referring to FIGS. 1 to 7, the pixel PXL and the display device DD including the same may include a base layer BSL, the circuit layer PCL, and a display layer DPL. The circuit layer PCL and the display layer DPL may be located to overlap each other on the base layer BSL. For example, the circuit layer PCL and the display layer DPL may be sequentially located on one surface of the base layer BSL.

In addition, the pixel PXL and the display device DD including the same may further include a color filter layer CFL and/or an encapsulation layer ENC (or a protective layer) located on the display layer DPL. In one or more embodiments, the color filter layer CFL and/or the encapsulation layer ENC may be directly formed on (e.g., over or above) one surface of the base layer BSL on which the circuit layer PCL and the display layer DPL are formed, but the disclosure is not limited.

The base layer BSL may be a rigid substrate or a flexible substrate or a film, and a material or a structure thereof is not particularly limited. For example, the base layer BSL may include at least one transparent or opaque insulating material, and may be a substrate or a film of single layer or multiple layers.

The circuit layer PCL may be provided on one surface of the base layer BSL. The circuit layer PCL may include circuit elements configuring the pixel circuit PXC of each pixel PXL. For example, a plurality of circuit elements including the first transistor M1 may be formed in each pixel area of the circuit layer PCL. In addition, the circuit layer PCL may include various signal lines and power lines connected to the pixels PXL of the display area DA.

Additionally, the circuit layer PCL may include a plurality of insulating layers. For example, the circuit layer PCL may include a buffer layer BFL, a gate insulating layer GI, an interlayer insulating layer ILD, and/or a passivation layer PSV sequentially located on one surface of the base layer BSL.

The circuit layer PCL may be located on the base layer BSL, and may include a first conductive layer including the bottom metal layer BML of the first transistor M1. For example, the first conductive layer may be located between the base layer BSL and the buffer layer BFL, and may include the bottom metal layer BML of the first transistor M1 provided in each pixel PXL. The bottom metal layer BML of the first transistor M1 may overlap a gate electrode GE and a semiconductor pattern SCP of the first transistor M1.

In addition, the first conductive layer may further include lines (e.g., predetermined lines). For example, the first conductive layer may include at least some lines extending in the second direction DR2 in the display area DA. For example, the first conductive layer may include the sensing line SENL, the data line DL, the first power line PL1 (or a second direction first sub power line), and/or the second power line PL2 (or a second direction second sub power line).

The buffer layer BFL may be located on one surface of the base layer BSL including the first conductive layer. The buffer layer BFL may reduce or prevent the likelihood of an impurity diffusing into each circuit element.

A semiconductor layer may be located on the buffer layer BFL. The semiconductor layer may include the semiconductor pattern SCP of the transistor M. The semiconductor pattern SCP may include a channel region overlapping the gate electrode GE of the corresponding transistor M, and first and second conductive regions (for example, source and drain regions) located on respective sides of the channel region. The semiconductor pattern SCP may be a semiconductor pattern formed of polysilicon, amorphous silicon, an oxide semiconductor, or the like.

The gate insulating layer GI may be located on the semiconductor layer. In addition, a second conductive layer may be located on the gate insulating layer GI.

The second conductive layer may include the gate electrode GE of each transistor M. In addition, the second conductive layer may further include one electrode of the capacitor Cst, a bridge pattern, and/or the like provided in the pixel circuit PXC. Additionally, when at least one power line and/or signal line located in the display area DA is configured of multiple layers, the second conductive layer may further include at least one conductive pattern configuring the at least one power line and/or signal line.

The interlayer insulating layer ILD may be located on the second conductive layer. In addition, a third conductive layer may be located on the interlayer insulating layer ILD.

The third conductive layer may include a source electrode SE and a drain electrode DE of each transistor M. The source electrode SE may be connected to one region (for example, the source region) of the semiconductor pattern SCP included in the corresponding transistor M through at least one contact hole CHs, and the drain electrode DE may be connected to another region (for example, the drain region) of the semiconductor pattern SCP included in the corresponding transistor M through at least one other contact hole CHd. In addition, the third conductive layer may further include another electrode of the capacitor Cst, lines (e.g., predetermined lines), a bridge pattern, and/or the like provided in the pixel circuit PXC. For example, the third conductive layer may include at least some of lines extending in the first direction DR1 in the display area DA. For example, the third conductive layer may include the scan lines SL, the control lines SSL, the first power line PL1 (or a first direction first sub power line), and/or the second power line PL2 (or a first direction second sub power line) connected to the pixels PXL. Additionally, when at least one power line and/or signal line located in the display area DA is configured of multiple layers, the third conductive layer may further include at least one conductive pattern configuring the at least one power line and/or signal line.

Each conductive pattern, electrode, and/or line configuring the first to third conductive layers may have conductivity by including at least one conductive material. For example, each conductive pattern, electrode, and/or line configuring the first to third conductive layers may include one or more metals selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), and copper (Cu), and may include various types of conductive materials.

The passivation layer PSV may be located on the third conductive layer. Each of the buffer layer BFL, the gate insulating layer GI, the interlayer insulating layer ILD, and the passivation layer PSV may be configured of a single layer or of multiple layers, and may include at least one inorganic insulating material and/or organic insulating material. For example, each of the buffer layer BFL, the gate insulating layer GI, the interlayer insulating layer ILD, and the passivation layer PSV may include various types of organic/inorganic insulating materials including silicon nitride (SiNₓ), silicon oxide (SiOₓ), silicon oxynitride (SiOₓN_{y}), and the like. In one or more embodiments, the passivation layer PSV may include an organic insulating layer, and may planarize a surface of the pixel circuit layer PCL.

The display layer DPL may be located on the passivation layer PSV.

The display layer DPL may include the light emitting unit EMU of each pixel PXL. For example, the display layer DPL may include the light emitting elements LD located in the emission area EA of each pixel PXL, and electrodes located around the light emitting elements LD. In one or more embodiments, the electrodes may include the first and second alignment electrodes ALE1 and ALE2 and the first and second contact electrodes CNE1 and CNE2, as in the embodiments corresponding to FIG. 6.

In addition, the display layer DPL may further include insulating patterns and/or insulating layers sequentially located on, or above, one surface of the base layer BSL on which the circuit layer PCL is formed. For example, the display layer DPL may include bank patterns BNP, a first insulating layer INS1, the first bank BNK1, the second insulating layer INS2, the third insulating layer INS3, a second bank BNK2, and/or a fourth insulating layer INS4. In addition, the display layer DPL may selectively further include a light conversion layer CCL.

The bank patterns BNP (also referred to as “patterns” or “wall patterns”) may be provided and/or formed on the passivation layer PSV. In one or more embodiments, the bank patterns BNP may be formed in separation type patterns individually located under the first and second alignment electrodes ALE1 and ALE2 to overlap a portion of each of the first and second alignment electrodes ALE1 and ALE2. For example, the bank patterns BNP may include the first bank pattern BNP1 located under the first alignment electrode ALE1, and the second bank pattern BNP2 located under the second alignment electrode ALE2.

In one or more embodiments, the bank patterns BNP may include at least one organic insulating layer including at least one organic insulating material. For example, the bank patterns BNP may be formed of organic insulating patterns including at least one of polyacrylate, polyimide, or other organic insulating material. Accordingly, the bank patterns BNP may be suitably formed in a desired size and/or height.

In one or more embodiments, the first bank pattern BNP1 and the second bank pattern BNP2 may have different widths and/or areas. For example, the first bank pattern BNP1 and the second bank pattern BNP2 may have different areas on a plane defined by the first direction DR1 and the second direction DR2. According to one or more embodiments, in the first direction DR1, the first bank pattern BNP1 may have a first width w1, and the second bank pattern BNP2 may have a second width w2 that is less than the first width w1.

In one or more embodiments, the first bank pattern BNP1 and the second bank pattern BNP2 may protrude, from one surface of the base layer BSL including the circuit layer PCL, at different heights, or thicknesses, in the third direction DR3 crossing the first direction DR1 and the second direction DR2. For example, in the third direction DR3, the first bank pattern BNP may have a first height h1, and the second bank pattern BNP may have a second height h2 that is lower than the first height h1.

The first height h1 may be sufficient to effectively reflect the light emitted at a low angle, which is emitted from the first end portions EP1 of the light emitting elements LD, in the upper direction of the pixel PXL according to a light output profile of the light emitting elements LD. The second height h2 may be sufficient to suitably form the second bank pattern BNP2 having the second width w2, and may be lower than the first height h1. The first height h1 and the second height h2 may vary according to a design condition or the like of the pixel PXL and the display device DD including the same.

At least one pair of alignment electrodes ALE may be formed on the bank patterns BNP. For example, the first and second alignment electrodes ALE1 and ALE2 may be formed on the bank patterns BNP. The number, shape, size, position, and/or the like of the alignment electrodes ALE located in each emission area EA may be changed according to one or more embodiments.

The alignment electrodes ALE may include at least one conductive material. For example, the alignment electrodes ALE may include at least one conductive material among at least one metal among various metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), and the like, an alloy thereof, a conductive oxide such as indium tin oxide (ITO), indium zinc oxide (IZO), indium tin zinc oxide (ITZO), zinc oxide (ZnO), aluminum doped zinc oxide (AZO), gallium doped zinc oxide (GZO), zinc tin oxide (ZTO), gallium tin oxide (GTO), and fluorine doped tin oxide (FTO), a conductive polymer such as PEDOT, or other conductive materials. A material used to form the alignment electrodes ALE is not particularly limited. The alignment electrodes ALE may include the same or different conductive materials.

Each alignment electrode ALE may be configured of a single layer or of multiple layers. In one or more embodiments, the alignment electrodes ALE may include a reflective electrode layer including a reflective conductive material for example, a metal such as aluminum (Al), gold (Au), and/or silver (Ag)) having high reflectivity in a visible light wavelength band. Accordingly, the light emitted from the light emitting elements LD may be reflected in the upper direction of the pixel PXL to increase the light output efficiency of the pixel PXL. The alignment electrodes ALE may further selectively include at least one of a transparent electrode layer located on and/or under the reflective electrode layer, and a conductive capping layer covering an upper portion of the reflective electrode layer and/or the transparent electrode layer.

The first insulating layer INS1 may be located on the alignment electrodes ALE. In one or more embodiments, the first insulating layer INS1 may be opened in an area where each alignment electrode ALE and each contact electrode CNE corresponding thereto overlap, and each alignment electrode ALE and each contact electrode CNE corresponding thereto may be electrically connected to each other in the area where the first insulating layer INS1 is opened. Alternatively, the first insulating layer INS1 may include at least one contact hole in the area where each alignment electrode ALE and each contact electrode CNE corresponding thereto overlap, and each alignment electrode ALE and each contact electrode CNE corresponding thereto may be electrically connected to each other through the at least one contact hole.

The first insulating layer INS1 may be configured of a single layer or of multiple layers, and may include at least one inorganic insulating material and/or an organic insulating material. In one or more embodiments, the first insulating layer INS1 may include at least one type of inorganic insulating material including silicon nitride (SiNₓ), silicon oxide (SiOₓ), or silicon oxynitride (SiOₓN_{y}).

As the alignment electrodes ALE are covered by the first insulating layer INS1, the likelihood of damage to the alignment electrodes ALE in a subsequent process may be reduced or prevented. In addition, the likelihood of an occurrence of a short defect due to an improper connection between the alignment electrodes ALE and the light emitting elements LD may be reduced or prevented.

The first bank BNK1 may be located on the display area DA in which the alignment electrodes ALE and the first insulating layer INS1 are formed. The first bank BNK1 may have the first opening OPA1 corresponding to the emission areas EA of each pixel PXL, and may be formed in the non-emission area NEA to surround each emission area EA. Accordingly, each emission area EA to which the light emitting elements LD are to be supplied may be defined (or partitioned). In one or more embodiments, the first bank BNK1 may include a light blocking and/or reflective material including a black matrix material or the like.

In one or more embodiments, the first bank BNK1 may include at least one organic insulating layer including at least one organic insulating material. Accordingly, the first bank BNK1 may be suitably formed in a desired size and/or height. The first bank BNK1 may include the same organic insulating material as the bank patterns BNP, or may include an organic insulating material that is different from that of the bank patterns BNP.

The light emitting elements LD may be located in each emission area EA surrounded by the first bank BNK1. For example, the light emitting elements LD may be arranged along the second direction DR2 in the first area AR1 between the first and second alignment electrodes ALE1 and ALE2, and each of the light emitting elements LD may be aligned in the first direction DR1 that crosses the direction DR2, or in an oblique direction. For example, each light emitting element LD may be located in a horizontal direction in the first area AR1 so that the first end portion EP1 is adjacent to the first alignment electrode ALE1, and so that the second end portion EP2 is adjacent to the second alignment electrode ALE2.

In one or more embodiments, each light emitting element LD may include the first semiconductor layer SCL1, the active layer ACT, the second semiconductor layer SCL2, and the electrode layer ETL sequentially located in a direction from the second end portion EP2 to the first end portion EP1. In addition, each light emitting element LD may further include the insulating film INF surrounding the outer circumferential surface (for example, a side surface of a cylinder) of the first semiconductor layer SCL1, the active layer ACT, the second semiconductor layer SCL2, and/or the electrode layer ETL.

In one or more embodiments, the active layer ACT may be located in a center area between the first end portion EP1 and the second end portion EP2, and may be located closer to the first end portion EP1 than the second end portion EP2. Accordingly, light generated from the active layer ACT may be generally emitted more toward the first end portion EP1 than to the second end portion EP2.

In one or more embodiments, the first contact electrode CNE1 that is substantially transparent may be located on the first end portions EP1 of the light emitting elements LD. Accordingly, the light emitted from the first end portions EP1 of the light emitting elements LD may pass through the first contact electrode CNE1. The reflective second contact electrode CNE2, which is substantially opaque, may be located on the second end portions EP2 of the light emitting elements LD. Accordingly, at least some of light directed from the active layer ACT of the light emitting elements LD toward the second end portions EP2 may be reflected by the second contact electrode CNE2, and may be emitted from the light emitting elements LD through other portions, such as the first end portions EP1 or the like.

The second insulating layer INS2 (also referred to as an “insulating pattern”) may be located on a portion of the light emitting elements LD. For example, the second insulating layer INS2 may be located locally on a portion including a central portion of the light emitting elements LD to expose the first and second end portions EP1 and EP2 of the light emitting elements LD arranged in the emission area EA of each pixel PXL. The light emitting elements LD may be stably fixed, and the first and second contact electrodes CNE1 and CNE2 may be more stably separated, by the second insulating layer INS2.

The second insulating layer INS2 may be configured of a single layer or of multiple layers, and may include at least one inorganic insulating material and/or organic insulating material. For example, the second insulating layer INS2 may include various types of organic and/or inorganic insulating materials including silicon nitride (SiNₓ), silicon oxide (SiOₓ), silicon oxynitride (SiOₓN_{y}), aluminum oxide (AlₓO_{y}), photoresist (PR) material, and the like.

The first contact electrode CNE1 and the second contact electrode CNE2 may be respectively located on the first and second end portions EP1 and EP2 of the light emitting elements LD, which are not covered by the second insulating layer INS2. In one or more embodiments, the first contact electrode CNE1 may be in direct contact with the first end portions EP1 of the light emitting elements LD, and the second contact electrode CNE2 may be in direct contact with the second end portions EP2 of the light emitting elements LD.

The first contact electrode CNE1 may be located on the first alignment electrode ALE1 to overlap at least a portion of the first alignment electrode ALE1. In one or more embodiments, the first contact electrode CNE1 may be electrically connected to the first alignment electrode ALE1. For example, the first contact electrode CNE1 may be in contact with the first alignment electrode ALE1 in an area where the first insulating layer INS1 is opened or removed (for example, an upper portion of the first bank pattern BNP1), to thereby be electrically connected to the first alignment electrode ALE1.

The second contact electrode CNE2 may be located on the second alignment electrode ALE2 to overlap at least a portion of the second alignment electrode ALE2. In one or more embodiments, the second contact electrode CNE2 may be electrically connected to the second alignment electrode ALE2. For example, the second contact electrode CNE2 may be in contact with the second alignment electrode ALE2 in an area where the first insulating layer INS1 is opened or removed (for example, an upper portion of the second bank pattern BNP2), to be electrically connected to the second alignment electrode ALE2.

The first contact electrode CNE1 may be formed as a transparent electrode including at least one transparent electrode layer, and the second contact electrode CNE2 may be formed as a reflective electrode including at least one reflective electrode layer. For example, the first contact electrode CNE1 may include at least one of ITO, IZO, ITZO, ZnO, AZO, GZO, ZTO, GTO, FTO, and other transparent conductive materials, and may be substantially transparent. The second contact electrode CNE2 may include at least one of a reflective conductive material having high reflectivity in a visible light wavelength band, for example, aluminum (Al), gold (Au), and silver (Ag), and other reflective metals, and may be substantially opaque. Accordingly, the light emitting elements LD may emit light through the first end portions EP1.

In one or more embodiments, the second contact electrode CNE2 may be formed of a conductive material capable of reducing a contact resistance at a contact surface with the light emitting elements LD. In one or more embodiments, the second contact electrode CNE2 may be formed by using a conductive material having a work function difference of about 0.5 eV or less, with the first semiconductor layer SCL1 located on the second end portions EP2 of the light emitting elements LD, or with at least one electrode layer located at the second end portions EP2 of the light emitting elements LD, to be adjacent to the first semiconductor layer SCL1. Accordingly, the contact resistance between the light emitting elements LD and the second contact electrode CNE2 may be reduced.

In one or more embodiments, the first contact electrode CNE1 and the second contact electrode CNE2 may be formed on different respective layers through different respective processes. For example, after the second contact electrode CNE2 is first formed, the third insulating layer INS3 may be formed on the second contact electrode CNE2. Thereafter, the first contact electrode CNE1 may be formed. The first contact electrode CNE1 may or may not overlap a portion of the third insulating layer INS3.

A disposition and/or a formation order of the first contact electrode CNE1 and the second contact electrode CNE2 may be changed. For example, in other embodiments, after the first contact electrode CNE1 is first formed, the third insulating layer INS3 may be formed on the first contact electrode CNE1. Thereafter, the second contact electrode CNE2 may be formed. In still other embodiments, the first contact electrode CNE1 and the second contact electrode CNE2 may be formed on the same layer.

In one or more embodiments, the third insulating layer INS3 may be formed on the first contact electrode CNE1 or the second contact electrode CNE2. In other embodiments, the third insulating layer INS3 may be omitted. For example, the pixel PXL may not include the third insulating layer INS3.

In one or more embodiments, the pixel PXL and the display device DD including the same may include the light conversion layer CCL located and/or provided in the emission area EA of each pixel PXL. For example, the light conversion layer CCL may be provided and/or located in the emission area EA, which includes the first area AR1, to be positioned on the light emitting elements LD located in each emission area EA.

In addition, the pixel PXL and the display device DD including the same may further include the second bank BNK2 located in the non-emission area NEA to overlap the first bank BNK1. The second bank BNK2 may define (or partition) each emission area EA in which the light conversion layer CCL is to be formed. In one or more embodiments, the second bank BNK2 may be integrated with the first bank BNK1.

The second bank BNK2 may include at least one light blocking and/or reflective material. For example, the second bank BNK2 may include at least one black matrix material and/or color filter material of a corresponding color. Accordingly, light leakage between adjacent pixels PXL may be reduced or prevented. The second bank BNK2 may include a material the same as, or different from, that of the first bank BNK1.

The light conversion layer CCL may include at least one of wavelength conversion particles (for example, color conversion particles) for converting a wavelength and/or a color of the light emitted from the light emitting elements LD, and may include light scattering particles SCT for increasing light output efficiency of the pixel PXL by scattering the light emitted from the light emitting elements LD. For example, in the emission area EA of each pixel PXL, the light conversion layer CCL includes wavelength conversion particles including at least one type of quantum dot QD (for example, the red quantum dot, the green quantum dot, and/or the blue quantum dot), and/or the scattering particles SCT.

For example, when any one pixel PXL is set as a red (or green) pixel, and when blue light emitting elements LD are provided in the emission area EA of the pixel PXL, the light conversion layer CCL including the red (or green) quantum dot QD for converting blue light into red (or green) light may be located in the emission area EA of the pixel PXL. The light conversion layer CCL may further selectively include the light scattering particles SCT.

The fourth insulating layer INS4 may be located on one surface of the base layer BSL including the light emitting units EMU and/or the light conversion layers CCL of the pixels PXL.

In one or more embodiments, the fourth insulating layer INS4 may include at least one organic insulating layer, and may substantially planarize a surface of the display layer DPL. The fourth insulating layer INS4 may protect the light emitting units EMU and/or the light conversion layers CCL of the pixels PXL.

The color filter layer CFL may be located on the fourth insulating layer INS4.

The color filter layer CFL may include color filters CF corresponding to colors of the pixels PXL. For example, the color filter layer CFL may include a first color filter CF1 located in the emission area EA of the first color pixel PXL1, a second color filter CF2 located in the emission area EA of the second color pixel PXL2, and a third color filter CF3 located in the emission area EA of the third color pixel PXL3. In one or more embodiments, the first, second, and third color filters CF1, CF2, and CF3 may be located to overlap each other in the non-emission area NEA to configure a light blocking pattern in the non-emission area NEA. In other embodiments, the first, second, and third color filters CF1, CF2, and CF3 may be formed to be separated from each other in the emission areas EA of the first color pixel PXL1, the second color pixel PXL2, and the third color pixel PXL3, respectively, and a separate light blocking pattern may be located between the first, second, and third color filters CF1, CF2, and CF3.

The encapsulation layer ENC may be located on the color filter layer CFL. The encapsulation layer ENC may include at least one organic insulating layer and/or an inorganic insulating layer including a fifth insulating layer INS5. The fifth insulating layer INS5 may be completely formed in the display area DA to cover the circuit layer PCL, the display layer DPL, and/or the color filter layer CFL. In one or more embodiments, the fifth insulating layer INS5 may include at least one organic insulating layer, and may planarize a surface of the display area DA.

According to the embodiments corresponding to FIGS. 6 and 7, the light emitting elements LD may be aligned so that the first end portion EP1 of each of the light emitting elements LD faces the first alignment electrode ALE1 and/or the first bank pattern BNP1, and second end portions EP2 of each of the light emitting elements LD faces the second alignment electrode ALE2 and/or the second bank pattern BNP2, and the plurality of the light emitting elements LD may be arranged along the second direction DR2 in the first area AR1. In addition, the light output profile of the light emitting elements LD may be controlled so that the light emitting elements LD emit light in one side through the first end portions EP1, by positioning the first contact electrode CNE1 formed as a transparent electrode on the first end portions EP1 of the light emitting elements LD, and by positioning the second contact electrode CNE2 formed as a reflective electrode on the second end portions EP2 of the light emitting elements LD.

Accordingly, a light emitting characteristic of the light emitting unit EMU may be controlled so that each light emitting unit EMU emits light in a form of a surface light source, and light may be more uniformly emitted from the emission area EA of each pixel PXL. When light is more uniformly emitted from the emission area EA, a concentration of light on wavelength conversion particles (for example, the quantum dot QD) of a corresponding area may be reduced or prevented, as compared to a case where the light emitting elements LD emit light in a form of individual point light sources. Accordingly, deterioration of the light conversion layer CCL (or the wavelength conversion particles included in the light conversion layer CCL), which may otherwise occur due to an optical power density (OPD) increase in an area where light is concentrated, may be reduced or prevented.

In case that the second contact electrode CNE2 formed of a reflective conductive material, such as a metal, is located on the second end portions EP2 of the light emitting elements LD, a contact resistance in the second end portions EP2 of the light emitting elements LD may be reduced. Accordingly, characteristics (for example, light emission characteristics) of the light emitting elements LD may be more uniform.

In addition, in the above-described embodiments, the first bank pattern BNP1 facing the first end portions EP1 of the light emitting elements LD may be formed and/or located in a size sufficient to effectively reflect the light that is emitted in the lateral direction from the light emitting elements LD to be redirected, generally, in the upper direction, at a distance sufficiently spaced apart from the light emitting elements LD (for example, may be formed a distance at which the light of a low angle, which is emitted in the lateral direction from the first end portions EP1 of the light emitting elements LD according to the light output profile of the light emitting elements LD, may be received and/or reflected by the presence of the first bank pattern BNP1). Accordingly, the light output efficiency of the pixel PXL may be increased.

In addition, in the above-described embodiments, a size of the second bank pattern BNP2 may be reduced or minimized, and the second bank pattern BNP2 may be located to be closer to the light emitting elements LD. Accordingly, the limited pixel area may be more efficiently utilized, and a space suitable for forming the first bank pattern BNP1 may be secured.

Additionally, in the above-described embodiments, the first contact electrode CNE1 that is transparent may be formed and/or located on the first end portions EP1 of the light emitting elements LD so that the light may be emitted through the first end portions EP1 (for example, the P-type end portion), which are closer to the active layer ACT than the respective second end portions EP2 (for example, the N-type end portion). Accordingly, the light output efficiency of the light generated by each light emitting element LD may be increased, and the light efficiency of the pixel PXL may be further increased.

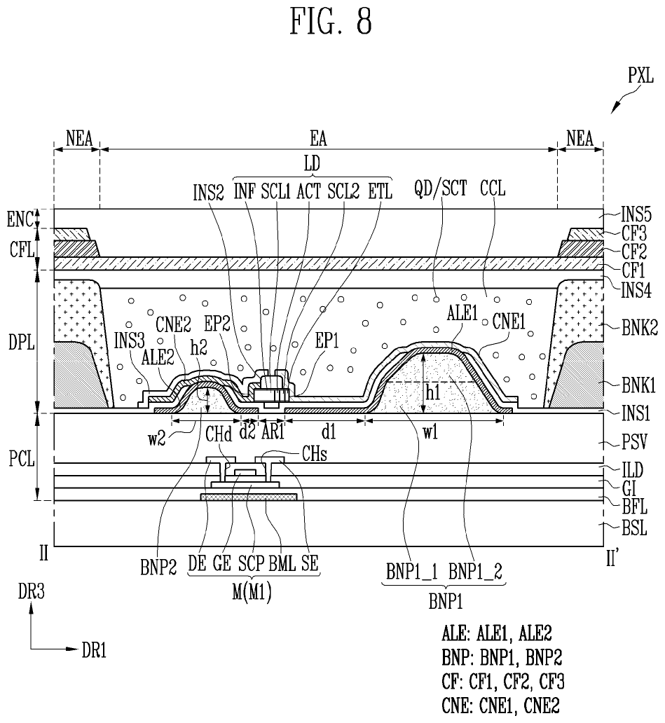

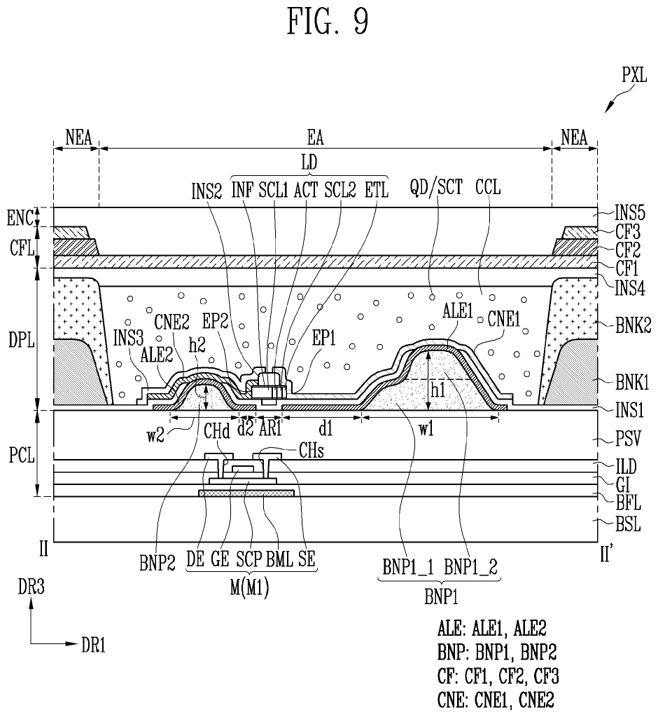

Referring to FIGS. 8 and 9, a surface profile of the first bank pattern BNP1 may be controlled for each area so as to be optimized for the light output characteristic (for example, the light output profile) of the light emitting elements LD. Accordingly, the light output efficiency of the pixel PXL may be further increased. For example, a slope or an inclination may be adjusted for each area and/or height corresponding to a surface of the first bank pattern BNP1 facing the light emitting elements LD (for example, a left sidewall of the first bank pattern BNP1 facing the first end portions EP1 of the light emitting elements LD), so that a corresponding range of light that is focused in the lateral direction may be more effectively reflected, according to the light output characteristics of the light emitting elements LD located in each emission area EA.

For example, the first bank pattern BNP1 may include a first portion BNP1_1 including a lower area at or below a middle height (e.g., a median height) of the first bank pattern BNP1, and a second portion BNP1_2 including an upper area at or above the middle height of the first bank pattern BNP1. On a surface where the first bank pattern BNP1 faces the light emitting elements LD, the first portion BNP1_1 and the second portion BNP1_2 of the first bank pattern BNP1 may be formed to have different surface profiles. In one or more embodiments, the surface profile of the first portion BNP1_1 and the second portion BNP1_2 of the first bank pattern BNP1 may be formed differently from each other by forming the first bank pattern BNP1 using a slit mask, a halftone mask, or the like.

In one or more embodiments, the light output profile of the light emitting elements LD may be concentrated on a lower angle range so that the light emitted from the light emitting elements LD is directed toward the first portion BNP 1_1, as opposed to the second portion BNP1_2 of the first bank pattern BNP1. In this case, as in the embodiments corresponding to FIG. 8, a slope or an inclination of the first portion BNP1_1 of the first bank pattern BNP1 may be increased on the surface where the first bank pattern BNP1 faces the light emitting elements LD. For example, on the surface where the first bank pattern BNP1 faces the light emitting elements LD, the first portion BNP1_1 of the first bank pattern BNP1 may have a slope or an inclination that is greater than that of the second portion BNP1_2. Accordingly, the light emitted from the light emitting elements LD may be controlled to be more directed toward the upper direction of the pixel PXL.

In one or more embodiments, the light output profile of the light emitting elements LD may be relatively concentrated in a middle angle range so that the light emitted from the light emitting elements LD is generally directed toward the first portion BNP1_1 of the first bank pattern BNP1, as opposed to the second portion BNP1_2 of the first bank pattern BNP1. In this case, as in the embodiments corresponding to FIG. 9, a slope or an inclination of the second portion BNP1_2 of the first bank pattern BNP1 may be increased on the surface where the first bank pattern BNP1 faces the light emitting elements LD. For example, on the surface where the first bank pattern BNP1 faces the light emitting elements LD, the second portion BNP1_2 of the first bank pattern BNP1 may have a slope or an inclination that is greater than that of the first portion BNP1_1. Accordingly, the light emitted from the light emitting elements LD may be controlled to be directed toward the upper direction of the pixel PXL.

According to the above-described embodiments, the light efficiency of the pixel PXL may be increased, and the light emission characteristics of the light emitting elements LD and the pixel PXL including the same may be uniformed. In addition, deterioration of the light conversion layer CCL may be prevented or reduced.

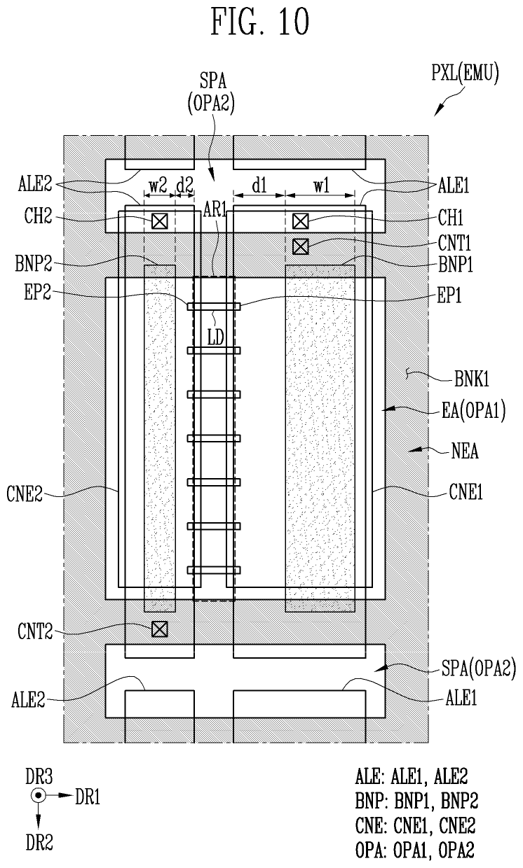

FIGS. 10 to 12 are respective plan views illustrating a pixel PXL according to one or more embodiments of the disclosure. For example, FIGS. 10 to 12 illustrate different modified embodiments of the embodiments corresponding to FIG. 6. In the embodiments of FIGS. 10 to 12, the same reference numerals are given to configurations that are similar to or identical to each other, or similar to or identical to those of the above-described embodiments (for example, the embodiments of FIGS. 6 to 9), and a detailed description of the repetitive parts is omitted.

Referring to FIG. 10, the first contact electrode CNE1 and the second contact electrode CNE2 may extend to the separation area SPA, and may be connected to the first alignment electrode ALE1 and the second alignment electrode ALE2 in the separation area SPA, respectively. For example, in the separation area SPA, the first contact electrode CNE1 may be electrically connected to the first alignment electrode ALE1 through a first contact hole CH1, and the second contact electrode CNE2 may be electrically connected to the second alignment electrode ALE2 through a second contact hole CH2.

In one or more embodiments, the first contact hole CH1 may be formed in an insulating layer (for example, the first insulating layer INS1 of FIGS. 7 to 9) located between the first alignment electrode ALE1 and the first contact electrode CNE1. The second contact hole CH2 may be formed in an insulating layer (for example, the first insulating layer INS1 of FIGS. 7 to 9) located between the second alignment electrode ALE2 and the second contact electrode CNE2. In one or more embodiments, the insulating layer may not be opened in the emission area EA, and thus may completely cover the first alignment electrode ALE1 and the second alignment electrode ALE2 in the light emission area EA.

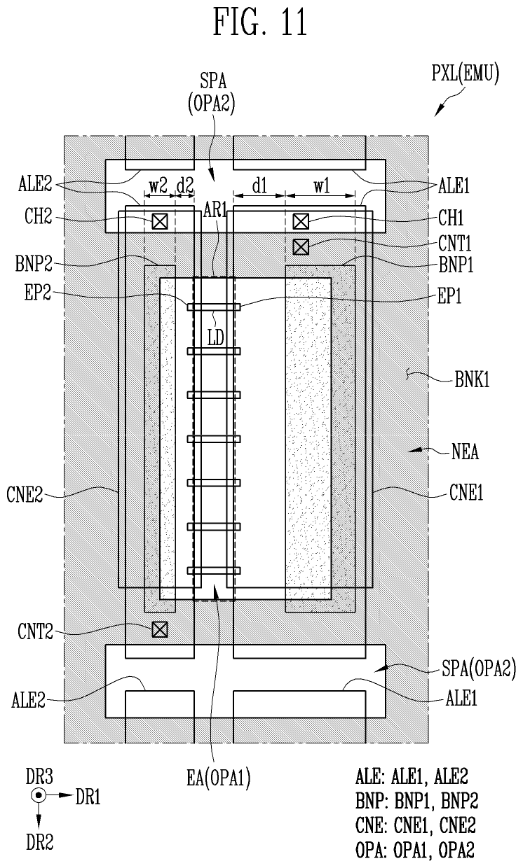

Referring to FIG. 11, at least one bank pattern BNP may overlap the first bank BNK1 in the first direction DR1. For example, compared to the embodiments corresponding to FIG. 10, a portion including an outer edge area of the first bank pattern BNP1 and the second bank pattern BNP2 in the first direction DR1 may overlap the first bank BNK1.

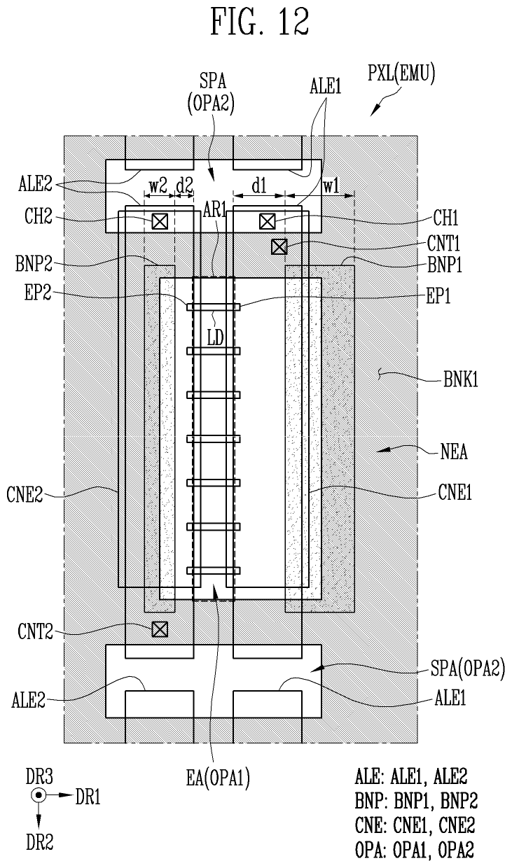

Referring to FIG. 12, the first alignment electrode ALE1 and/or the first contact electrode CNE1 may overlap only a portion of the first bank pattern BNP1 in the first direction DR1, and might not overlap another portion of the first bank pattern BNP1. For example, compared to the embodiments corresponding to FIG. 11, widths of the first alignment electrode ALE1 and the first contact electrode CNE1 in the first direction DR1 may be reduced. In addition, the first alignment electrode ALE1 and the first contact electrode CNE1 may be located on only a portion of the first bank pattern BNP1 including a sidewall (for example, a left sidewall) of the first bank pattern BNP1 facing the first end portions EP1 of the light emitting elements LD. In this case, a width of each pixel area and/or separation area SPA may be reduced.

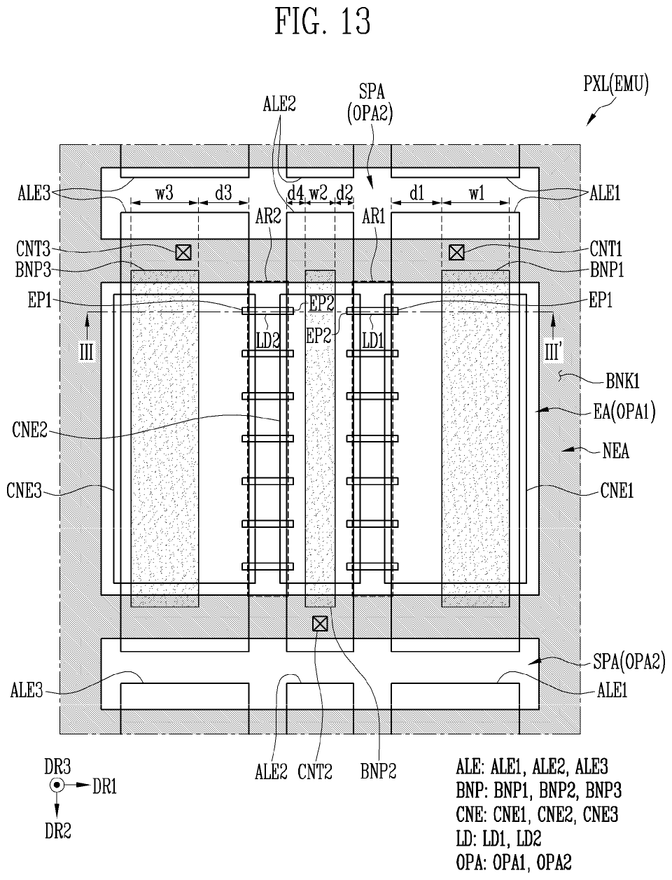

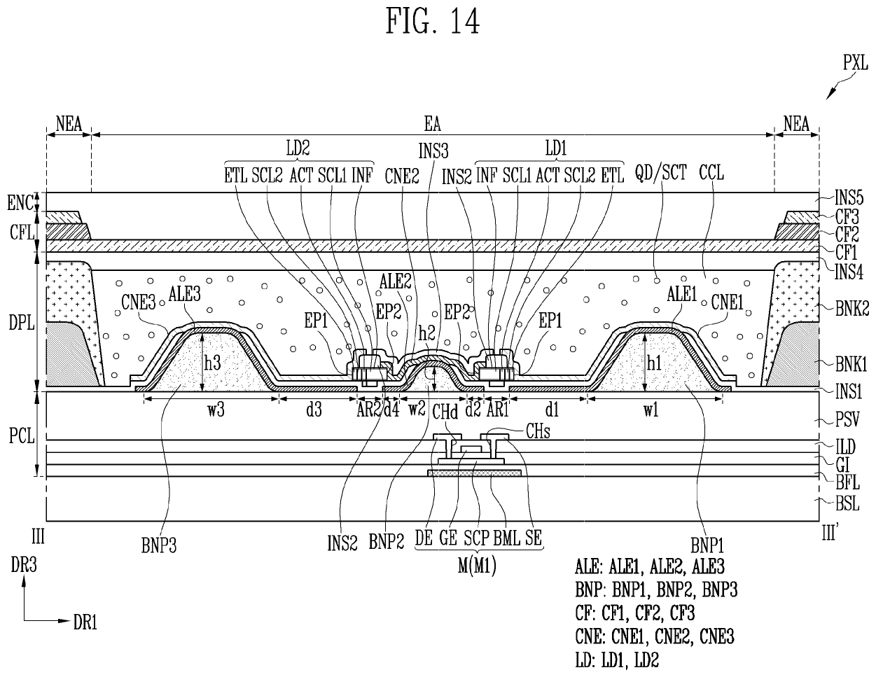

FIG. 13 is a plan view illustrating a pixel PXL according to one or more embodiments of the disclosure. For example, FIG. 13 illustrates a modified example of the embodiments corresponding to FIG. 6. FIG. 14 is a cross-sectional view illustrating a pixel PXL according to one or more embodiments of the disclosure. For example, FIG. 14 illustrates a cross sectional view of a pixel PXL taken along the line III˜III′ of FIG. 13. In the embodiments of FIGS. 13 and 14, the same reference numerals are given to configurations similar to or identical to those of the above-described embodiments, and a detailed description of repetitive parts is omitted.

Referring to FIGS. 13 and 14, the pixel PXL may further include a third bank pattern BNP3, a third alignment electrode ALE3 (also referred to as a “third electrode”), and a third contact electrode CNE3. The light emitting elements LD configuring the effective light source of the pixel PXL may include light emitting elements LD (hereinafter, referred to as “first light emitting elements LD1”) located and/or arranged in the first area AR1 between the first alignment electrode ALE1 and the second alignment electrode ALE2, and light emitting elements LD (hereinafter, referred to as “second light emitting elements LD2”) located and/or arranged in a second area AR2 between the second alignment electrode ALE2 and the third alignment electrode ALE3.

The third bank pattern BNP3 may overlap a portion of the third alignment electrode ALE3, and may be located under the third alignment electrode ALE3. The third bank pattern BNP3 may be located around the first end portions EP1 of the second light emitting elements LD2, and may face the first end portions EP1 of the second light emitting elements LD2.

The third bank pattern BNP3 may or may not overlap the first bank BNK1. For example, a portion of the third bank pattern BNP3 may be located in the emission area EA, and another portion of the third bank pattern BNP3 (for example, at least one end portion of the third bank pattern BNP3) may be located in the non-emission area NEA to overlap the first bank BNK1. Alternatively, the third bank pattern BNP3 may be located only in the emission area EA so as not to overlap the first bank BNK1.

The third bank pattern BNP3 may face the first bank pattern BNP1 with the second bank pattern BNP2 interposed therebetween. In one or more embodiments, the first bank pattern BNP1 and the third bank pattern BNP3 may be formed to be symmetrical to each other with the second bank pattern BNP2 interposed therebetween (for example, based on the second bank pattern BNP2).

The second bank pattern BNP2 and the third bank pattern BNP3 may be formed to be asymmetrical to each other based on the second area AR2. For example, the second bank pattern BNP2 and the third bank pattern BNP3 may be spaced apart from the second area AR2 by different distances, and/or may be formed in different sizes.

The third bank pattern BNP3 may be spaced apart from the second area AR2 by a third distance d3. In one or more embodiments, the third distance d3 may be substantially the same as or similar to the first distance d1.

The second bank pattern BNP2 may be spaced apart from the second area AR2 by a fourth distance d4. In one or more embodiments, the fourth distance d4 may be less than the third distance d3, and may be substantially the same as or similar to the second distance d2. For example, the second bank pattern BNP2 may be located closer to the first and second areas AR1 and AR2 than the first bank pattern BNP1 and the third bank pattern BNP3. The first bank pattern BNP1 and the third bank pattern BNP3 may be located at a greater distance from the first area AR1 and the second area AR2 than the second bank pattern BNP2, respectively.

In one or more embodiments, the third distance d3 may be determined according to a path and/or a distribution of light emitted from the second light emitting elements LD2. For example, the third distance d3 may be set to a value within a range that is capable of effectively reflecting a light of a lateral direction directed at a relatively low angle, and not generally directed toward the upper direction of the pixel PXL, among the light emitted from the first end portions EP1 of the second light emitting elements LD2.

In one or more embodiments, the fourth distance d4 may be set to a value that is less than the third distance d3 in consideration of the limited pixel area. Accordingly, the limited pixel area may be efficiently utilized, and a separation distance between the third bank pattern BNP3 and the second area AR2 may be sufficiently secured.

The third bank pattern BNP3 may be formed in a sufficient size to effectively reflect a greater proportion of the light of a low angle that is emitted from the first end portions EP1 of the second light emitting elements LD2. In one or more embodiments, the third bank pattern BNP3 may have a greater size (for example, greater width, area, height, and/or volume) than the second bank pattern BNP2. For example, the third bank pattern BNP3 may have a third width w3 in the first direction DR1, and the third width w3 may be greater than the second width w2. In addition, the third bank pattern BNP3 may have a third height h3 in the third direction DR3, and the third height h3 may be greater than the second height h2.

In one or more embodiments, in case that the first bank pattern BNP1 and the third bank pattern BNP3 are symmetrical to each other, the first bank pattern BNP1 and the third bank pattern BNP3 may have substantially the same or similar widths in the first direction DR1, and may have substantially the same or similar heights in the third direction DR3. For example, the first width w1 and the third width w3 may be substantially the same or similar, and the first height h1 and the third height h3 may be substantially the same or similar. In the third direction DR3, each of the first bank pattern BNP1 and the third bank pattern BNP3 may protrude at a greater height than that of the second bank pattern BNP2. Accordingly, light output efficiency of light emitted from the first and second light emitting elements LD1 and LD2 may be increased.

In one or more embodiments, the first bank pattern BNP1 may be formed to have a profile that is capable of effectively reflecting the light, which is emitted from the first light emitting elements LD1 toward the upper direction of the pixel PXL, on a surface (for example, a left sidewall of the first bank pattern BNP1) facing the first light emitting elements LD1. The third bank pattern BNP3 may be formed to have a profile, which is capable of effectively reflecting the light emitted from the second light emitting elements LD2 in the upper direction of the pixel PXL, on a surface (for example, a right sidewall of the third bank pattern BNP3) facing the second light emitting elements LD2. In one or more embodiments, the first bank pattern BNP1 and the third bank pattern BNP3 may have shapes substantially symmetrical to each other.

The third alignment electrode ALE3 may be located around the first end portions EP1 of the second light emitting elements LD2. The third alignment electrode ALE3 may or may not overlap the first end portion EP1 of each of the second light emitting elements LD2.

Before the pixel process for forming the pixels PXL, for example, the alignment of the light emitting elements LD is completed, the third alignment electrodes ALE3 of the pixels PXL may be connected to each other to configure a third alignment line. The third alignment line may receive a third alignment signal different from the second alignment signal in the alignment operation of the light emitting elements LD. Accordingly, an electric field may be formed between the second and third alignment lines, and thus the second light emitting elements LD2 may be aligned between the second and third alignment lines.

For example, the second light emitting elements LD2 may be arranged along the second direction DR2 in an area (for example, the second area AR2) between the second and third alignment lines by second and third alignment signals respectively applied to the second and third alignment lines in the light emitting element alignment operation. Each of the second light emitting elements LD2 may be aligned in a horizontal direction in the second area AR2 so that the first end portion EP1 is adjacent to the third alignment electrode ALE3, and so that the second end portion EP2 is adjacent to the second alignment electrode ALE2.

After the alignment of the light emitting elements LD is completed, the third alignment line may be cut off in each separation area SPA to separate the third alignment electrodes ALE3 of the pixels PXL from each other.

In one or more embodiments, the first alignment line and the third alignment line may be electrically connected to each other, and may receive the same alignment signal. For example, the third alignment signal may be the same signal as the first alignment signal. In other embodiments, the first alignment line and the third alignment line may be electrically separated from each other, and may receive different alignment signals.

The third alignment electrode ALE3 may overlap the third bank pattern BNP3, and may protrude in the third direction DR3 in an area where the third alignment electrode ALE3 overlaps the third bank pattern BNP3. A third protrusion pattern may be formed on one side (for example, a left side) of the second area AR2 by the third alignment electrode ALE3 and the third bank pattern BNP3. In addition, a second protrusion pattern may be formed on another side (for example, a right side) of the second area AR2 by the second alignment electrode ALE2 and the second bank pattern BNP2. A position where the second light emitting elements LD2 are aligned and/or arranged may be suitably controlled by the second and third protrusion patterns.

In addition, the third protrusion pattern may form a reflective wall structure. Accordingly, the light efficiency of the pixel PXL may be increased.

In one or more embodiments, the third alignment electrode ALE3 may be electrically connected to the third contact electrode CNE3. For example, the third alignment electrode ALE3 may be in direct contact with the third contact electrode CNE3 inside and/or outside the emission area EA to be electrically connected to the third contact electrode CNE3, or may be electrically connected to the third contact electrode CNE3 through at least one contact hole or the like. In addition, the third alignment electrode ALE3 may be connected to a circuit element, a bridge pattern, a line, and/or the like of the circuit layer PCL through a third contact portion CNT3.

The third contact portion CNT3 may include at least one contact hole and/or via hole. In one or more embodiments, the third contact portion CNT3 may be located outside the emission area EA. For example, the third contact portion CNT3 may be located in the non-emission area NEA so as to overlap the first bank BNK1, or may be located in the separation area SPA so as not to overlap the first bank BNK1. A position of the third contact portion CNT3 may be changed.

The first light emitting elements LD1 may be arranged along the second direction DR2 in the first area AR1, and the second light emitting elements LD2 may be arranged along the second direction DR2 in the second area AR2. Each of the first light emitting elements LD1 may include the first end portion EP1 adjacent to the first alignment electrode ALE1, and the second end portion EP2 adjacent to the second alignment electrode ALE2. Each of the second light emitting elements LD2 may include the first end portion EP1 adjacent to the third alignment electrode ALE3, and the second end portion EP2 adjacent to the second alignment electrode ALE2. In one or more embodiments, the first light emitting elements LD1 may correspond to the light emitting elements LD arranged in the first area AR1 described in the embodiments of FIGS. 6 to 12.

In one or more embodiments, the first light emitting elements LD1 and the second light emitting elements LD2 may be connected to each other in parallel. For example, the first end portions EP1 of the first light emitting elements LD1 may be electrically connected to the first contact electrode CNE1, and may be electrically connected to the first alignment electrode ALE1 through the first contact electrode CNE1. The first end portions EP1 of the second light emitting elements LD2 may be electrically connected to the third contact electrode CNE3, and may be electrically connected to the third alignment electrode ALE3 through the third contact electrode CNE3. The third alignment electrode ALE3 may be electrically connected to the first alignment electrode ALE1 through the third contact portion CNT3, the pixel circuit PXC and the like, or may be formed integrally with the first alignment electrode ALE1 to be electrically connected to the first alignment electrode ALE1. The second end portions EP2 of the first light emitting elements LD1 and the second end portions EP2 of the second light emitting elements LD2 may be commonly connected to the second contact electrode CNE2, and may be electrically connected to the second power line PL2 through the second contact electrode CNE2 and/or the second alignment electrode ALE2. For example, the second contact electrode CNE2 may be commonly located on the second end portions EP2 of the first light emitting elements LD1 and on the second end portions EP2 of the second light emitting elements LD2 to be electrically connected to the second end portions EP2 of the first light emitting elements LD1 and the second end portions EP2 of the second light emitting elements LD2.

In one or more embodiments, each light emitting element LD (for example, each of first light emitting element LD1 or each second light emitting element LD2) may be an ultra-small (for example, having a size of a range of nanometer to micrometer) inorganic light emitting element of using a material of an inorganic crystalline structure. In one or more embodiments, the first light emitting elements LD1 and the second light emitting elements LD2 may be light emitting elements LD of substantially the same or similar types, structures, and/or sizes.

The third contact electrode CNE3 may be located on the third alignment electrode ALE3 and the first end portions EP1 of the second light emitting elements LD2. In one or more embodiments, the third contact electrode CNE3 may be electrically connected to the first end portions EP1 of the second light emitting elements LD2. For example, the third contact electrode CNE3 may be directly on the first end portions EP1 of the second light emitting elements LD2 to be in contact with the first end portions EP1 of the second light emitting elements LD2.

In one or more embodiments, the third contact electrode CNE3 may be electrically connected to the third alignment electrode ALE3, and may be electrically connected to the pixel circuit PXC and/or the first power line PL1 through the third alignment electrode ALE3. In other embodiments, the third contact electrode CNE3 may be electrically connected to the pixel circuit PXC and/or the first power line PL1 through means other than the third alignment electrode ALE3.

In one or more embodiments, the third contact electrode CNE3 may be a transparent electrode including at least one transparent electrode layer, and the second contact electrode CNE2 may be a reflective electrode including at least one reflective electrode layer as in the above-described embodiments. For example, the third contact electrode CNE3 may be formed as a transparent electrode of a single layer or of multiple layers including at least one transparent conductive material, and the second contact electrode CNE2 may be formed as a reflective electrode of a single layer or of multiple layers including at least one reflective conductive material. Accordingly, the second light emitting elements LD2 may emit light to one side through the first end portions EP1 of the first and second end portions EP1 and EP2.

In one or more embodiments, the third contact electrode CNE3 may be formed concurrently or substantially simultaneously with the first contact electrode CNE1 using the same material as the first contact electrode CNE1. The third contact electrode CNE3 may be formed to be connected to the first contact electrode CNE1 or may be formed to be separated from the first contact electrode CNE1.

At least some of the light emitted through the first end portions EP1 of the second light emitting elements LD2 may be reflected by the third protrusion pattern formed by the third bank pattern BNP3 and the third alignment electrode ALE3, and may be subsequently emitted in the upper direction of the pixel PXL including the third direction DR3 in an area where the third bank pattern BNP3 is formed. Accordingly, the light output efficiency of the light generated in the pixel PXL may be increased.

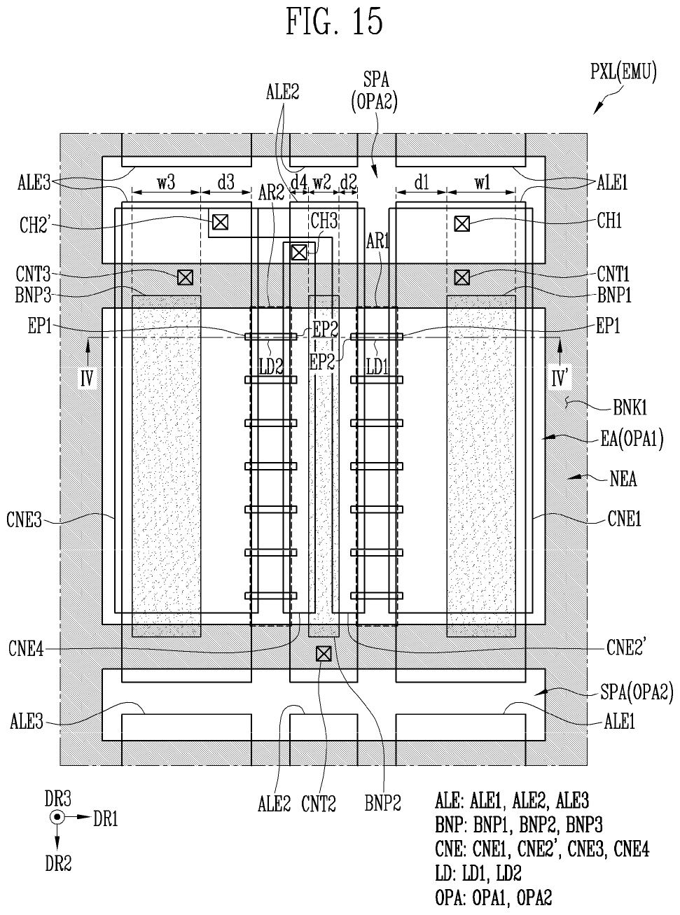

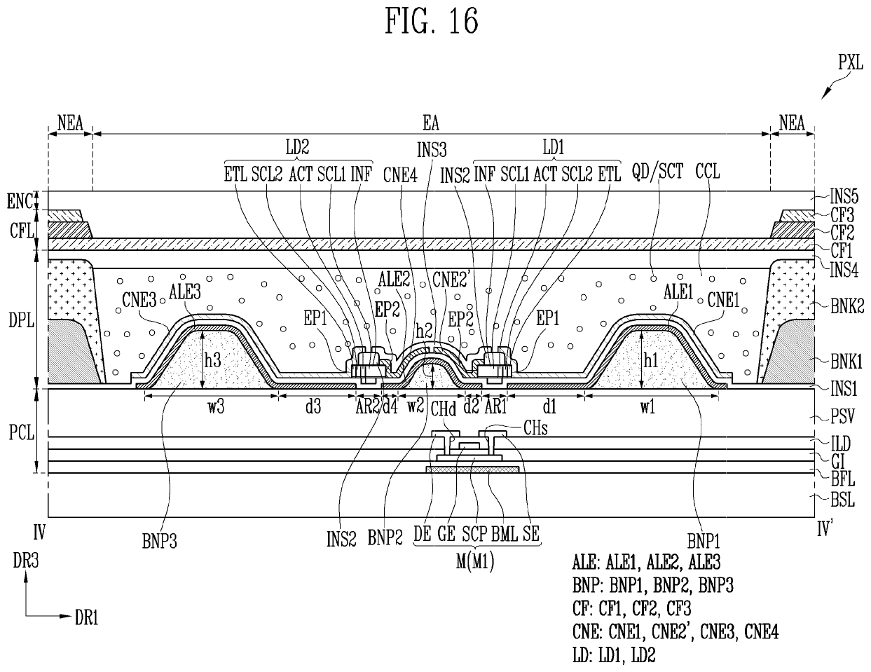

FIG. 15 is a plan view illustrating a pixel PXL according to one or more embodiments of the disclosure. For example, FIG. 15 illustrates a modified example of the embodiments corresponding to FIG. 13. FIG. 16 is a cross-sectional view illustrating a pixel PXL according to one or more embodiments of the disclosure. For example, FIG. 16 illustrates a cross sectional view of the pixel PXL taken along the line IV˜IV′ of FIG. 15. In the embodiments corresponding to FIGS. 15 and 16, the same reference numerals are given to configurations similar to or identical to those of the above-described embodiments (for example, the embodiments of FIGS. 13 and 14), and a detailed description of repetitive parts is omitted.

Referring to FIGS. 15 and 16, the pixel PXL may include first light emitting elements LD1 and second light emitting elements LD2 connected in series with each other through contact electrodes CNE. For example, the pixel PXL may include a light emitting unit EMU of a series-parallel structure.

The contact electrodes CNE may include a first contact electrode CNE1, a second contact electrode CNE2′, a third contact electrode CNE3, and a fourth contact electrode CNE4.

The first contact electrode CNE1 may be located on the first end portions EP1 of the first light emitting elements LD1, and may be electrically connected to the first end portions EP1 of the first light emitting elements LD1. The first contact electrode CNE1 may be electrically connected to the first alignment electrode ALE1 through the first contact hole CH1 or the like, and may be electrically connected to the first power line PL1 through the first alignment electrode ALE1 and/or the pixel circuit PXC. The first contact electrode CNE1 may be a transparent electrode including a transparent electrode layer.

The second contact electrode CNE2′ may be located on the second end portions EP2 of the first light emitting elements LD1, and may be electrically connected to the second end portions EP2 of the first light emitting elements LD1. The second contact electrode CNE2′ may be separated from the fourth contact electrode CNE4, and may be electrically connected to the third contact electrode CNE3. For example, the second contact electrode CNE2′ may be formed to be spaced apart from the fourth contact electrode CNE4, and may be electrically connected to the third contact electrode CNE3 through a second contact hole CH2′ or the like. The second contact electrode CNE2′ may not be directly connected to the second alignment electrode ALE2. The second contact electrode CNE2′ may be a reflective electrode including a reflective electrode layer.

The third contact electrode CNE3 may be located on the first end portions EP1 of the second light emitting elements LD2, and may be electrically connected to the first end portions EP1 of the second light emitting elements LD2. The third contact electrode CNE3 may not be directly connected to the third alignment electrode ALE3. The third contact electrode CNE3 may be a transparent electrode including a transparent electrode layer.

The fourth contact electrode CNE4 may be located on the second end portions EP2 of the second light emitting elements LD2, and may be electrically connected to the second end portions EP2 of the second light emitting elements LD2. The fourth contact electrode CNE4 may be electrically connected to the second alignment electrode ALE2 through a third contact hole CH3 or the like, and may be electrically connected to the second power line PL2 through the second alignment electrode ALE2. The fourth contact electrode CNE4 may be a reflective electrode including a reflective electrode layer.

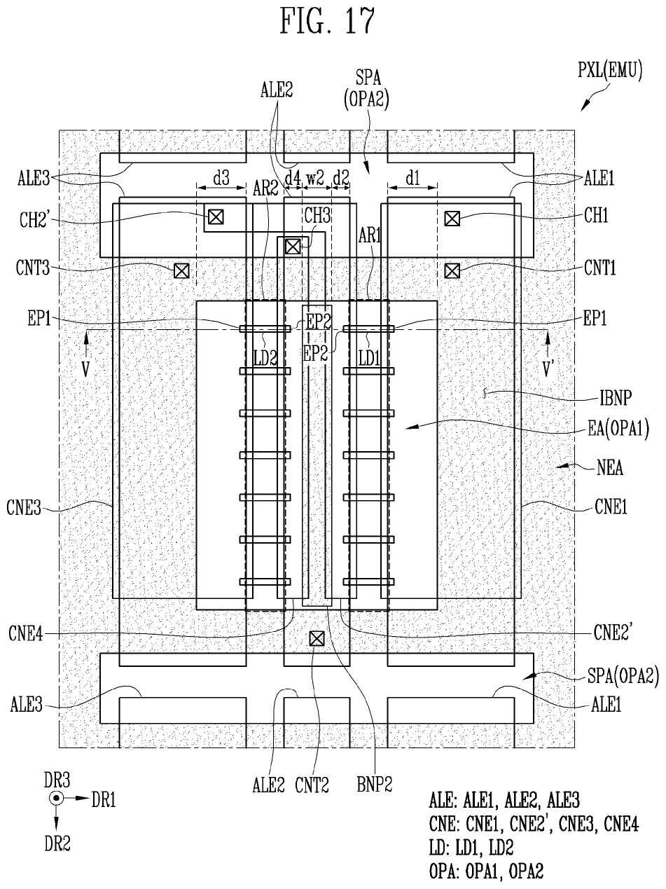

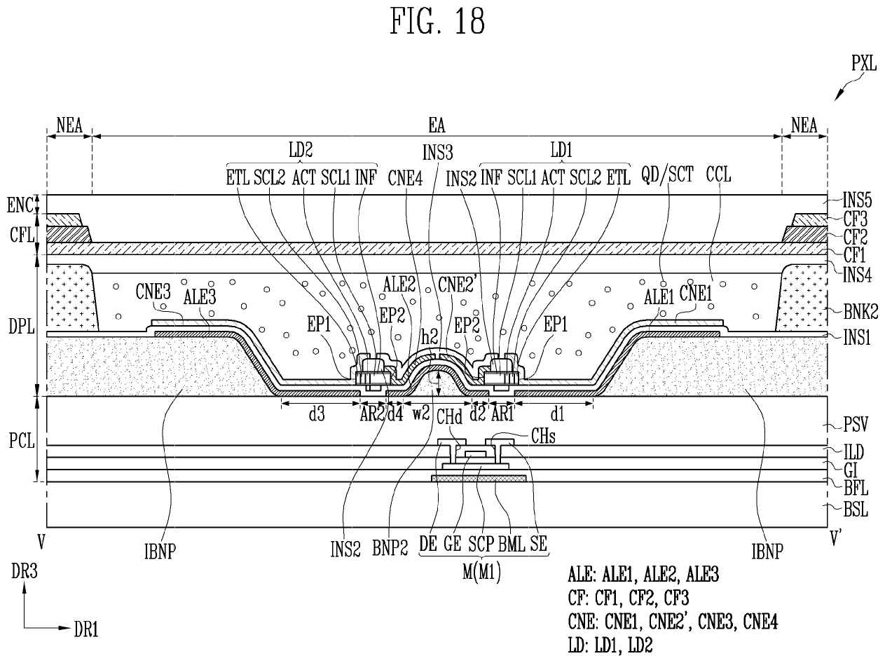

FIG. 17 is a plan view illustrating a pixel PXL according to one or more embodiments of the disclosure. For example, FIG. 17 illustrates a modified example of the embodiments corresponding to FIG. 15. FIG. 18 is a cross-sectional view illustrating a pixel PXL according to one or more embodiments of the disclosure. For example, FIG. 18 illustrates a cross sectional view of the pixel PXL taken along the line V˜V′ of FIG. 17. In the embodiments corresponding to FIGS. 17 and 18, the same reference numerals are given to configurations similar to or identical to those of the above-described embodiments (for example, the embodiments of FIGS. 15 and 16), and a detailed description of repetitive parts is omitted.

Referring to FIGS. 17 and 18, the first bank pattern BNP1, the third bank pattern BNP3, and the first bank BNP1 disclosed in the above-described embodiments (for example, the embodiments of FIGS. 13 to 16) may be integrated into one bank pattern IBNP (hereinafter, referred to as an “integrated bank pattern”).

For example, the pixel PXL may include the emission area EA in which at least a portion of each of the alignment electrodes ALE (for example, the first, second, and third alignment electrodes ALE1, ALE2, and ALE3), the contact electrodes CNE (for example, the first, second, and third contact electrodes CNE1, CNE2, and CNE3) and/or the second bank pattern BNP2, as well as the light emitting elements LD (for example, the first and second light emitting elements LD1 and LD2), are located. The integrated bank pattern IBNP, which may effectively include the first bank pattern BNP1, the third bank pattern BNP3, and the first bank BNK1, may completely surround the emission area EA of the pixel PXL in a plane defined by the first direction DR1 and the second direction DR2.

According to the above-described embodiments, a mask (for example, a mask used for a pixel process) used for manufacturing the display device DD may be reduced. Accordingly, a manufacturing process of the display device DD may be simplified, and manufacturing efficiency may be increased.

According to the various embodiments of the present disclosure as described above, the light emitting elements LD may be arranged along the second direction DR2 between at least one pair of alignment electrodes ALE. Each light emitting element LD may have the first end portion EP1 and the second end portion EP2 in a direction (for example, the first direction DR1) crossing the second direction DR2. The first contact electrode CNE1 including a transparent electrode layer may be located on the first end portions EP1 of the light emitting elements LD, and the second contact electrode CNE2 including a reflective electrode layer may be located on the second end portions EP2 of the light emitting elements LD. Accordingly, the light emitting elements LD may emit light through the first end portions EP1 of the first and second end portions EP1 and EP2, and the light emitting unit EMU may emit light in a form of a surface light source. Accordingly, the light emission characteristics of each pixel PXL may be made relatively uniform, and deterioration of the light conversion layer CCL may be reduced or prevented.

In the above-described embodiments, the first bank pattern BNP1 and/or the third bank pattern BNP3 facing the first end portions EP1, and configured to reflect the light of the lateral direction so that the light (for example, light emitted at a low angle within a range (e.g., a predetermined range)) may be emitted upwardly from the pixel PXL, may be located around the first end portions EP1 of the light emitting elements LD. The first bank pattern BNP1 and/or the third bank pattern BNP3 may form the first protrusion pattern and/or the third protrusion pattern facing the first end portions EP1 of the light emitting elements LD, together with the first alignment electrode ALE1 and/or the third alignment electrode ALE3 located thereon. The first bank pattern BNP1 and/or the third bank pattern BNP3 may be designed in a sufficient size (for example, a sufficient height) at a position where the first bank pattern BNP1 and/or the third bank pattern BNP3 may reflect light emitted from the light emitting elements LD and directed toward a side surface of the pixel PXL. Accordingly, the light efficiency (for example, the light output efficiency of the light generated in the light emitting elements LD) of the pixel PXL may be increased.

In the above-described embodiments, a second bank pattern BNP2 for guiding an arrangement position of the light emitting elements LD together with the first bank pattern BNP1 and/or the third bank pattern BNP3 may be located around the second end portions EP2 of the light emitting elements LD. The second bank pattern BNP2 may have a size that is less than that of the first bank pattern BNP1 and/or the third bank pattern BNP3, and may be located closer to the light emitting elements LD. Accordingly, the limited pixel area may be efficiently utilized, and a space suitable for forming the first bank pattern BNP1 and/or the third bank pattern BNP3 may be secured.

In one or more embodiments, the first end portions EP1 of the light emitting elements LD may be P-type end portions closer to respective active layers ACT. Accordingly, the light output efficiency of the light generated in the light emitting elements LD may be increased.

In one or more embodiments, a surface profile of the first bank pattern BNP1 may be controlled for each area to be improved or optimized with respect to the light output characteristic of the light emitting elements LD (for example, to be optimized for reflection of the light emitted from the light emitting elements LD in the lateral direction). In embodiments in which the pixel PXL further includes the third bank pattern BNP3, a surface profile of the third bank pattern BNP3 may also be controlled for each area to be optimized to the light output characteristic of the light emitting elements LD with respect to the third bank pattern BNP3. Accordingly, the light efficiency of the pixel PXL may be more effectively increased.

In one or more embodiments, the pixel PXL may include the first and third bank patterns BNP1 and BNP3 that are located on both edge areas of the emission area EA, and that form the protrusion patterns that reflect the light generated by the light emitting elements LD. In one or more embodiments, the first and third bank patterns BNP1 and BNP3 may have substantially similar or identical sizes to each other, and may be formed symmetrically to each other. The first and third bank patterns BNP1 and BNP3 may be integrated with the first bank BNK1 for defining the emission area EA or the like of each pixel PXL. Accordingly, a mask used for forming the pixels PXL may be reduced, and manufacturing efficiency of the display device DD may be increased.

Although the technical idea or spirit of the disclosure has been described in detail in accordance with the above-described embodiments, it should be noted that the above-described embodiments are for the purpose of description and not of limitation. In addition, those skilled in the art may understand that various modifications are possible within the scope of the technical idea or spirit of the disclosure.

The scope of the disclosure is not limited to the details described in the detailed description of the specification, but should be defined by the claims, with functional equivalents thereof to be included therein. It is to be construed that all changes or modifications derived from the meaning and scope of the claims and equivalent concepts thereof are included in the scope of the disclosure.

What is claimed is:

1. A pixel comprising:
a first electrode and a second electrode spaced apart from each other along a first direction;
first light emitting elements arranged along a second direction in a first area between the first electrode and the second electrode, and comprising a first end portion adjacent to the first electrode and a second end portion adjacent to the second electrode;
a first contact electrode on the first end portions of the first light emitting elements, and comprising a transparent electrode layer;
a second contact electrode on the second end portions of the first light emitting elements, and comprising a reflective electrode layer;
a first bank pattern overlapping a portion of the first electrode beneath the first electrode; and
a second bank pattern overlapping a portion of the second electrode beneath the second electrode,
wherein the first bank pattern and the second bank pattern are spaced apart from the first area by different distances.

2. The pixel according to claim 1, wherein the first bank pattern is spaced apart from the first area by a first distance in the first direction, and
wherein the second bank pattern is spaced apart from the first area in the first direction by a second distance that is shorter than the first distance.

3. The pixel according to claim 1, wherein the first bank pattern and the second bank pattern have different widths in the first direction.

4. The pixel according to claim 3, wherein the first bank pattern has a first width in the first direction, and
wherein the second bank pattern has a second width in the first direction that is narrower than the first width.

5. The pixel according to claim 1, wherein the first bank pattern and the second bank pattern protrude at different heights in a third direction that crosses the first direction and the second direction.

6. The pixel according to claim 5, wherein the first bank pattern has a first height in the third direction, and
wherein the second bank pattern has a second height in the third direction that is less than the first height.

7. The pixel according to claim 1, wherein the first bank pattern comprises:
a first portion comprising a lower area having a height at or below a middle height of the first bank pattern; and
a second portion comprising an upper area having a height at or above the middle height of the first bank pattern, and
wherein the first portion has a slope or an inclination that is greater than that of the second portion on a surface where the first bank pattern faces the first light emitting elements.

8. The pixel according to claim 1, wherein the first bank pattern comprises:
a first portion comprising a lower area having a height at or below a middle height of the first bank pattern; and
a second portion comprising an upper area having a height at or above than the middle height of the first bank pattern, and
wherein the second portion of the first bank pattern has a slope or an inclination that is greater than that of the first portion of the first bank pattern on a surface where the first bank pattern faces the first light emitting elements.

9. The pixel according to claim 1, further comprising:
a third electrode facing the first electrode in the first direction with the second electrode therebetween;
second light emitting elements arranged along the second direction in a second area between the second electrode and the third electrode, and comprising a first end portion adjacent to the third electrode and a second end portion adjacent to the second electrode;
a third contact electrode on the first end portions of the second light emitting elements, and comprising a transparent electrode layer; and
a third bank pattern overlapping a portion of the third electrode beneath the third electrode,
wherein the second bank pattern and the third bank pattern are spaced apart from the second area by different distances.

10. The pixel according to claim 9, wherein the first bank pattern is at a greater distance from the first area in the first direction than the second bank pattern, and
wherein the third bank pattern is at a greater distance from the second area in the first direction than the second bank pattern.

11. The pixel according to claim 9, wherein the first bank pattern and the third bank pattern protrude at a greater height than the second bank pattern in a third direction crossing the first direction and the second direction.

12. The pixel according to claim 9, wherein the first bank pattern and the third bank pattern are symmetrical to each other with the second bank pattern interposed therebetween.

13. The pixel according to claim 9, further comprising an emission area where at least a portion of the first, second, and third electrodes, the first, second, and third contact electrodes, the second bank pattern, and the first and second light emitting elements are located,
wherein the first bank pattern and the third bank pattern are integrated into an integrated bank pattern.

14. The pixel according to claim 13, wherein the integrated bank pattern completely surrounds the emission area in a plan view.

15. The pixel according to claim 9, wherein the second contact electrode is commonly on the second end portions of the first light emitting elements, and on the second end portions of the second light emitting elements.

16. The pixel according to claim 9, further comprising a fourth contact electrode on the second end portions of the second light emitting elements, and comprising a reflective electrode layer,
wherein the second contact electrode is separated from the fourth contact electrode, and is electrically connected to the third contact electrode.

17. The pixel according to claim 1, wherein the first light emitting elements comprise an active layer between the first end portion and the second end portion and closer to the first end portion than to the second end portion.

18. The pixel according to claim 1, further comprising a light conversion layer on the first light emitting elements in an emission area comprising the first area, the light conversion layer comprising at least one of wavelength conversion particles and light scattering particles.

19. A display device comprising a pixel in a display area, the pixel comprising:
a first electrode and a second electrode spaced apart from each other along a first direction;
first light emitting elements arranged along a second direction in a first area between the first electrode and the second electrode, and comprising a first end portion adjacent to the first electrode and a second end portion adjacent to the second electrode;
a first contact electrode on the first end portions of the first light emitting elements, and comprising a transparent electrode layer;
a second contact electrode on the second end portions of the first light emitting elements, and comprising a reflective electrode layer;
a first bank pattern overlapping a portion of the first electrode beneath the first electrode; and
a second bank pattern overlapping a portion of the second electrode beneath the second electrode,
wherein the first bank pattern and the second bank pattern are spaced apart from the first area by different distances.

20. The display device according to claim 19, wherein the first bank pattern is spaced apart from the first area in the first direction by a greater distance than the second bank pattern, and
wherein the first bank pattern protrudes at a height that is higher than that of the second bank pattern in a third direction crossing the first direction and the second direction.
